(19) United States
(12) Patent Application Publication
(10) Pub. No.: US 2009/0176995 A1
(43) Pub. Date: Jul. 9, 2009

(54) Soluble fullerene derivatives

(75) Inventors: Takeshi Toru, Togo-cho (JP); Norio Shibata, Nagoya (JP); Shuichi Nakamura, Nagoya (JP); Tetsuo Soga, Nagoya (JP); Yasuhiko Hayashi, Nagoya (JP); Surya Prakash Singh, Mino (JP)

Correspondence Address: OLIFF & BERRIDGE, PLC, P.O. BOX 320850, ALEXANDRIA, VA, 22320-4850, US

(73) Assignee: NATIONAL UNIVERSITY CORPORATION NAGOYA INSTITUTE OF TECHNOLOGY, Nagoya (JP)

(21) Appl. No.: 12/292,886

(22) Filed: Nov. 28, 2008

(30) Foreign Application Priority Data
Nov. 29, 2007 (JP) 2007-309476

(51) Int. Cl. C07D 333/56; C07C 317/14; C07C 49/825; C07C 69/78; C07C 205/06

(52) U.S. Cl. 549/58; 568/33; 568/331; 560/101; 560/57; 568/928

(57) ABSTRACT

Disclosed are soluble diarylmethanofullerene derivatives that are effective as acceptors for organic thin-film solar batteries. They help to constitute effective organic thin-film solar batteries.

### CROSS REFERENCE TO RELATED APPLICATION

This application is based upon and claims the benefit of Japanese Patent Application No. 2007-309476 filed on Nov. 29, 2007, the content of which are incorporated herein by reference.

### FIELD OF THE INVENTION

The present invention relates to soluble fullerene derivatives that are useful as acceptor semiconductors for organic thin-film solar batteries.

### RELATED ART OF THE INVENTION

Fullerenes are used as acceptors (n-type molecules) for organic thin-film solar batteries. The known fullerenes are made into thin films via vacuum vapor deposition, because fullerenes themselves are sparingly soluble in organic solvents. To form such thin films typically via spin coating of a solution of a fullerene in an organic solvent, PCBM ([6,6]-phenyl-C61-butyric acid methyl ester) has been developed and widely used in researches. However, although being soluble in dichlorobenzene and toluene, PCBM is also sparingly soluble in other widely-used solvents.

Organic thin-film solar batteries each include a donor molecule and an acceptor molecule (fullerene). The donor molecule is excited by the action of light, and releases and transfers the excited electron to the acceptor molecule. The acceptor molecule receives the electron and transfers the same to an electrode. Exemplary donor molecules include, as low-molecular compounds, phthalocyanine, poly(3-hexylthiophene) abbreviated as P3HT, poly(2-methoxy-5-(3′,7′-dimethyloctyloxy)-1,4-phenylenevinylene) abbreviated as MDMOPPV, and poly(2-methoxy-5-ethylhexyloxy-1,4-phenylenevinylene) abbreviated as MEHPPV. To form solar batteries, a solution of such a donor molecule in combination with a fullerene as an acceptor molecule should be used.

### SUMMARY OF THE INVENTION

Development of novel fullerene derivatives are desired to develop novel organic thin films for organic thin-film solar batteries. For developing fullerene derivatives that are applicable to a variety of donor semiconductors, demands have been made to allow fullerene derivatives to have solubility in widely-used organic solvents, in contrast to original fullerenes and PCBM. Namely, original fullerenes are insoluble in such widely-used organic solvents, and PCBM is soluble only in few of such widely-used organic solvents. According to the present invention, however, such fullerene derivatives having such solubility are first provided.

Specifically, known fullerenes are insoluble in organic solvent, and PCBM is soluble only in toluene and o-dichlorobenzene. After intensive investigations to improve the solubility of these acceptor molecules to thereby develop fullerene derivatives that are soluble in widely-used organic solvents, the present inventors have found soluble fullerene derivatives that help to develop heterojunction photoelectric conversion layers not only with known donor semiconductors such as phthalocyanine, HDMO-PPV, and P3HT, but also with donors of every kind. Fullerene derivatives according to the present invention show high solubility in organic solvents and, if used as acceptor components, form photoelectric conversion layers that show high photoelectric conversion efficiencies and are thereby very effective.

Specifically, according to a first embodiment of the present invention, a methanofullerene derivative represented by following Chemical Formula (1) is used as an acceptor component for organic thin-film solar batteries:

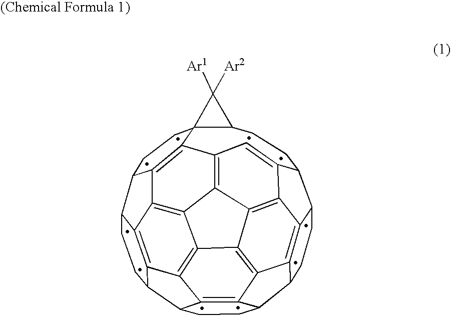

wherein Ar¹ and Ar² are the same or different substituents,

Ar¹ represents any one of:

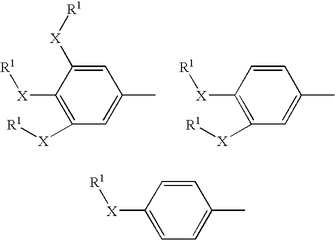

wherein R¹s each represent an alkyl group having one to fifteen carbon atoms, and X represents an oxygen or sulfur atom; and

Ar² represents YnC₆H₄, wherein Y represents a hydrogen or one or more substituents selected typically from among CO₂R², R³SO₂, NO₂ group, and cyano group, wherein R² represents an alkyl group having one to fifteen carbon atoms, R³ represents a methyl group, a trifluoromethyl group, or a phenyl group; and “n” denotes an integer of from 1 to 5.

According to a second embodiment of the present invention, a methanofullerene-C₆₁ derivative represented by following Chemical Formula (2) is used as an acceptor component for organic thin-film solar batteries:

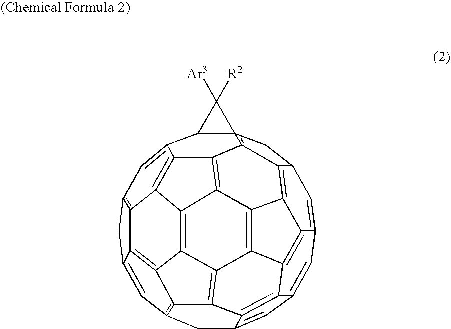

wherein Ar³ represents a phenyl group, a substituted phenyl group, or a benzothiazolyl group, wherein the substituted phenyl group is selected typically from a pentafluorophenyl group or

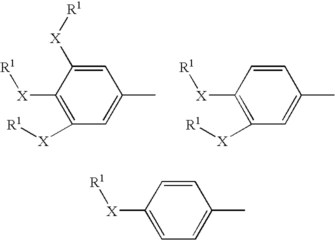

wherein R¹s each represent an alkyl group having one to fifteen carbon atoms, and X represents an oxygen or sulfur atom; and

R² represents a linear or branched alkyl group having one to twenty carbon atoms, -Q-X—Ar⁴, -Q-CO₂—CH₂Ar¹, or —CO₂—CH₂CH₂—Rf, wherein Q represents a (poly)methylene group having one to eight carbon atoms, X represents an oxygen atom or sulfur atom, and Ar⁴ represents a phenyl group, a substituted phenyl group, a naphthyl group, or a benzothiophene; wherein Ar¹ is as defined in Chemical Formula (1); and wherein Rf represents a perfluoroalkyl group having one to ten carbon atoms. In other embodiments, methanofullerene-C₇₁ derivatives may be used as acceptor components, which methanofullerene-C₇₁ derivatives are represented by following Chemical Formulae (3) and (4), respectively, and correspond to the methanofullerene derivative represented by Chemical Formula (1) and to the methanofullerene-C₆, derivative represented by Chemical Formula (2), except for having a C₇₀ fullerene skeleton instead of the C₆₀ fullerene skeleton:

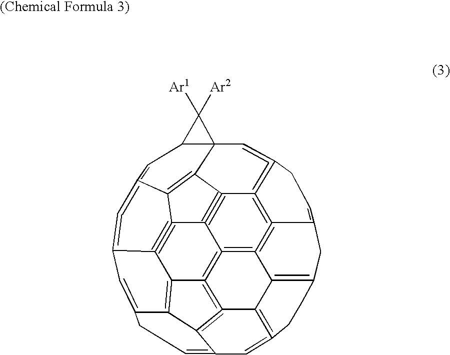

wherein Ar¹ and Ar² are as defined above;

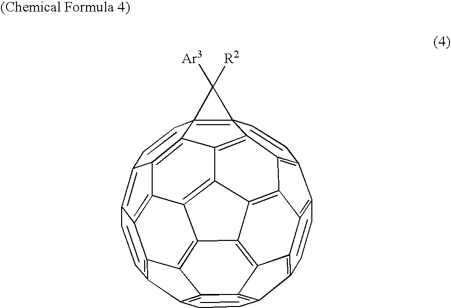

wherein Ar³ and R² are as defined above.

In this connection, there is known a soluble fullerene derivative represented by following Chemical Formula (5) and called PCBM as an acceptor component for organic thin-film solar batteries. PCBM, however, shows solubility only in aromatic hydrocarbons such as toluene and o-dichlorobenzene and are thereby applicable only to a narrow range of solvents, which significantly impedes the development of organic thin-film solar batteries.

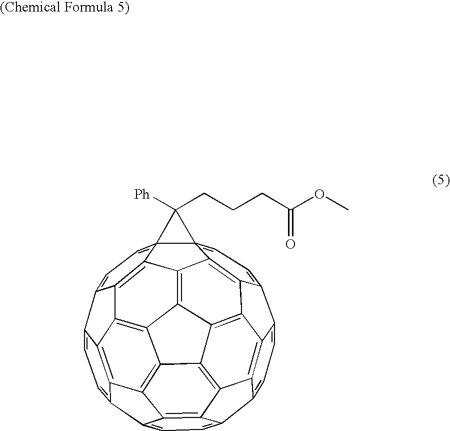

In contrast, according to the first and second embodiments of the present invention, the following advantages can be obtained.

Specifically, solar batteries are globally widely demanded technologies, because such solar batteries are expected to be major energy sources in the next generation. Among them, organic thin-film solar batteries are significantly expected technologies, in which inexpensive organic thin-films are used as a donor component and an acceptor component, respectively, to convert solar energy to electricity. As a matter of course, the photoelectric conversion efficiencies of such organic thin-films vary depending on properties of the thin films. In other words, the development of organic compounds showing high photoelectric conversion efficiencies is key to develop practicable organic thin-film solar batteries.

The compounds according to the present invention are significantly improved in solubility in organic solvents as compared to known fullerene compounds and are thereby very useful for the production of organic thin-film solar batteries that show high photoelectric conversion efficiencies.

### BRIEF DESCRIPTION OF THE DRAWINGS

Other objects, features and advantages of the present invention will be understood more fully from the following detailed description made with reference to the accompanying drawings. In the drawings:

FIG. 1 is an exemplary diagram illustrating a cell used in the measurement of performance of organic thin-film solar batteries.

### DETAILED DESCRIPTION OF THE PREFERRED EMBODIMENTS

The present invention will be described further with reference to various embodiments in the drawings.

Methanofullerene-C₆, derivatives (1) and (2) and methanofullerene-C₇, derivatives (3) and (4) can each be obtained by reacting a corresponding ketone with a sulfonylhydrazide to give a sulfonylhydrazone; heating the sulfonylhydrazone with fullerene-C₆₀ or -C₇₀ in pyridine in the presence of sodium methoxide to give a compound; and readily isomerizing the compound through the application of heat or light. The resulting methanofullerene-C₆₁ derivatives and methanofullerene-C₇₁ derivatives obtained through reactions can be easily purified by silica gel column chromatography. The purities of purified products can be determined by high-performance liquid chromatography (HPLC), and the structures thereof can be identified typically based on H-NMR, C13-NMR, IR spectral analysis, and/or UV spectral analysis.

More specifically, the reaction is conducted by using a sulfonylhydrazide in an amount of preferably 1 to 20 equivalents, and more preferably 2 to 5 equivalents, to the ketone. Exemplary sulfonylhydrazides for use herein include p-toluenesulfonylhydrazide and benzenesulfonylhydrazide. Exemplary solvents include alcohol solvents such as methanol, ethanol, propanol, and butanol; aprotic polar solvents such as dimethylformamide and dimethyl sulfoxide; ethyl acetate; and halogenated solvents such as chloroform, dichloroethane, and trichloroethane. The reaction is carried out at temperatures of from 40° C. to 150° C. The resulting sulfonylhydrazone may be used in the subsequent step with or without purification by silica gel column chromatography or recrystallization.

Next, the sulfonylhydrazone is reacted with fullerene-C₆₀ or -C₇₀. The solvent used herein is pyridine or a mixture of pyridine with benzene, toluene, chlorobenzene, o-dichlorobenzene, p-dichlorobenzene, o-xylene, m-xylene, or p-xylene. This reaction is carried out in the presence of a base. The base herein may be, for example, sodium methoxide, sodium ethoxide, sodium t-butoxide, potassium methoxide, potassium ethoxide, potassium t-butoxide, or lithium hexamethyldisilazide. The amount of the base is 0.8 to 5 equivalents. The reaction is carried out at temperatures of from 50° C. to 150° C., and preferably from 60° C. to 120° C. After heating for 3 to 48 hours, aftertreatment is conducted to give a crude product, the crude product is purified by silica gel chromatography or by the removal of the base and other unnecessary components, the purified product is dissolved in the solvent and then subjected to isomerization from “5,6”-isomer into “6,6”-cyclopropane isomer by heating at temperatures of 60° C. to 150° C., heating under acidic conditions, or applying light from a sodium lamp. Thus, the target methanofullerene-C₆₁ derivatives (1) and (2) and methanofullerene-C₇₁ derivatives (3) and (4) can be obtained.

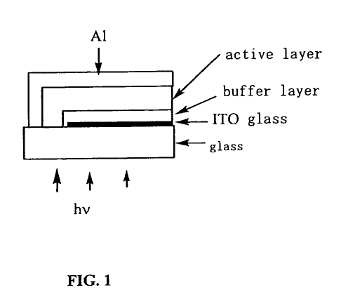

The fullerene derivatives according to the present invention are significantly advantageously usable as acceptors for organic thin-film solar batteries. The performance (properties) as an organic thin-film solar battery can be measured typically with a cell illustrated in FIG. 1.

The battery cell illustrated in FIG. 1 is prepared in the following manner. Initially, a buffer layer is formed on an indium tin oxide (ITO) transparent electrode via spin coating typically of a poly(3,4-ethyldioxythiophene)-poly(styrenesulfonate) abbreviated as PEDOT-PSS; next, a mixture solution containing a donor and an acceptor is applied thereonto via spin coating to form a photoelectric conversion layer; and a thin film of aluminum is deposited thereon by vapor deposition. The donor may be selected from electroconductive polymers such as a poly(3-hexylthiophene) abbreviated as P3HT, a poly(2-methoxy-5-(3′,7′-dimethyloctyloxy)-1,4-phenylenevinylene) abbreviated as MDMOPPV, and a poly(2-methoxy-5-ethylhexyloxy-1,4-phenylenevinylene) abbreviated as MEHPPV; and phthalocyanine derivatives. The acceptor herein is a methanofullerene-C₆₁ derivative or methanofullerene-C₇₁ derivative. The photoelectric conversion layer is formed by dissolving P3HT, MDMOPPV, or MEHPPV and the methanofullerene derivative in a solvent such as o-dichlorobenzene in a ratio of from 1:0.5 to 1:5 to give a solution; applying the solution via spin coating to give a film; and heating the coated film at temperatures of from 50° C. to 120° C.

After the vapor deposition of aluminum, the article is heated at temperatures of from 60° C. to 150° C. for 10 minutes to 48 hours to thereby give an organic thin-film solar battery cell. When a phthalocyanine derivative is used as a donor, a solution is prepared by dissolving the phthalocyanine derivative and the fullerene derivative in a ratio of from 1:0.5 to 1:5 in a solvent, and the solution is applied via spin coating.

Exemplary solvents for use in this process include ether solvents such as tetrahydrofuran, dioxane, dimethoxyethyl ether, diethylene glycol dimethyl ether, and diethylene glycol diethyl ether; nitrile solvents such as acetonitrile and propionitrile; halogenated solvents such as chloroform, dichloroethane, trichloroethane, and carbon tetrachloride; aprotic polar solvents such as dimethylformamide and dimethylacetamide; and heterocyclic compounds such as pyridine, pyrazine, and pyrimidine.

Solubility in a variety of organic solvents features the methanofullerene-C₆₁ derivatives and methanofullerene-C₇₁ derivatives according to the present invention. Specifically, these fullerene derivatives, if used as an acceptor, can give an organic thin film with a phthalocyanine derivative as a corresponding donor molecule. Exemplary solvents herein include ether solvents such as tetrahydrofuran, dioxane, dimethoxyethyl ether, diethylene glycol dimethyl ether, and diethylene glycol diethyl ether; nitrile solvents such as acetonitrile and propionitrile; halogenated solvents such as chloroform, dichloroethane, trichloroethane, and carbon tetrachloride; aprotic polar solvents such as dimethylformamide and dimethylacetamide; and heterocyclic compounds such as pyridine, pyrazine, and pyrimidine.

The phthalocyanine derivative used as the donor is preferably one having a substituent such as t-butyl group.

The formation and measurement of such organic thin films are preferably carried out in an atmosphere of inert gas such as nitrogen or argon gas.

Some embodiments and examples of the present invention will be illustrated below. It should be noted, however, that these are never construed to limit the scope of the present invention.

### Example 1

### Synthesis of 3,5-Didecyloxybenzyl 4-(1-phenyl-C61)butyrate

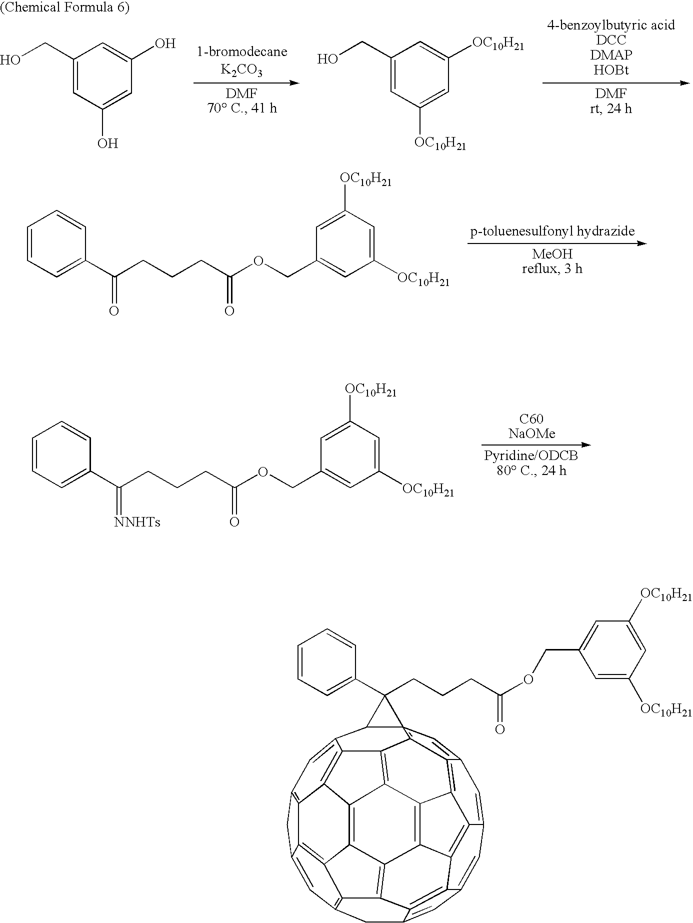

### (1) Synthesis of 3,5-Didecyloxybenzyl Alcohol

In a 100-ml eggplant flask was placed 3.95 g (20.5 mmol) of potassium carbonate. After purging the flask with nitrogen, 15 ml of DMF was added. Next, 1.00 g (7.13 mmol) of 3,5-dihydroxybenzyl alcohol and 3.3 ml (15.0 mmol) of 1-bromodecane were added, followed by stirring at 70° C. for 41 hours. The reaction mixture was allowed to cool to room temperature, from which insoluble matter was removed by filtration through Celite, and the filtrate was washed with methylene chloride. The solvent was distilled off on a rotary evaporator, and the residue was dissolved in diethyl ether and washed with a saturated aqueous sodium hydrogen carbonate solution and with a saturated aqueous sodium chloride solution. The washed solution was dried over magnesium sulfate, filtrated, and concentrated while distilling off the solvent on a rotary evaporator. The resulting crude product was purified by silica gel chromatography (hexane/AcOEt=70/30) and thereby yielded 1.54 g of the target compound in a yield of 51%.

¹H NMR (CDCl₃, 200 MHz): 6.47 (d, J=2, 2H), 6.36 (t, J=4, 1H), 4.56 (br, s 2H), 3.94 (t, J=8.6, 4H), 1.78 (m, 4H), 1.41 (m, 28H), 0.87 (t J=6.6, 6H).

### (2) Synthesis of 3,5-Didecyloxybenzyl 4-Benzoylbutyrate

In a 20-ml eggplant flask was placed 100 mg (0.500 mmol) of 4-benzoylbutyric acid. After purging the flask with nitrogen, 3.0 ml of DMF was added to give a solution, followed by ice-cooling. A solution of 107 mg (0.500 mmol) of DCC in 1.0 ml of DMF was slowly added, followed by stirring at room temperature for 12 hours. Next, 30.5 mg (0.250 mmol) of dimethylaminopyridine and 4.0 mg (0.025 mmol) of 1-hydroxybenzotriazole were added, the mixture was stirred at room temperature for 1 hour, and a solution of 231 mg (0.550 mmol) of 3,5-didecyloxybenzyl alcohol in 1.0 ml of DMF was slowly added, followed by stirring at room temperature for 24 hours. The solvent was distilled off on a rotary evaporator, the resulting crude product was purified by silica gel column chromatography (hexane/AcOEt=95/5) and thereby yielded 173 mg of the target compound in a yield of 53%.

¹H NMR (CDCl₃, 200 MHz): 7.89 (d, 2H, J=6.0 Hz), 7.53-7.30 (m, 3H), 6.54 (s, 2H), 6.37 (s, 1H), 5.03 (s, 2H), 3.88 (t, 4H, J=6.4 Hz), 3.0 (t, 2H, J=7.0 Hz), 2.47 (t, 2H, J=7.2 Hz), 2.14-1.99 (m, 2H), 1.73 (t, 4H, J=6.4 Hz), 1.26 (m, 28H), 0.87 (t, 6H, J=5.2 Hz). ¹³C NMR (CDCl₃, 50.3 MHz): 14.19, 19.40, 22.73, 26.09, 29.27, 29.36, 29.43, 29.61, 31.91, 33.30, 37.30, 66.03, 67.82, 100.66, 106.04, 127.60, 128.15, 132.57, 136.36, 137.58, 159.94, 172.36, 198.42. IR (CH₂Cl₂): 3443, 2925, 2854, 1736, 1687, 1597, 1450, 1166, 1063, 689 cm⁻¹

### (3) Synthesis of 3,5-Didecyloxybenzyl 5-(2-Tosylhydrazono)-5-phenylpentanoate

In a 10-ml eggplant flask were placed 50 mg (0.080 mmol) of 3,5-didecyloxybenzyl 4-benzoylbutyrate and 17 mg (0.090 mmol) of p-toluenesulfonylhydrazide, and subsequently 4.0 ml of MeOH was added to give a solution. The solution was heated under reflux for 3 hours, followed by stirring at room temperature for 12 hours. The solvent was distilled off on a rotary evaporator, the resulting crude product was purified by silica gel column chromatography (hexane to hexane/AcOEt=75/25) and thereby yielded 59 mg of the target compound in a yield of 80%.

¹H NMR (CDCl₃, 200 MHz): 9.22 (s, 1H), 7.86 (d, 2H, J=8.2 Hz), 7.64 (m, 3H), 7.32 (m, 4H), 6.49 (s, 2H), 6.42 (s, 1H), 5.13 (s, 2H), 3.93 (t, 4H, J=6.4 Hz), 2.62 (t, 2H, J=8.0 Hz), 2.38 (m, 5H), 1.78 (m, 6H), 1.26 (m, 28H), 0.88 (t, 6H, J=6.8 Hz). ¹³C NMR (CDCl₃, 50.3 MHz): 14.31, 21.13, 21.74, 22.83, 25.97, 26.19, 29.38, 29.45, 29.52, 29.70, 32.01, 32.36, 67.15, 68.09, 101.06, 106.24, 106.56, 125.94, 127.67, 128.16, 129.21, 135.74, 135.85, 137.07, 143.34, 153.25, 160.25, 173.86. Anal. Calcd. for C₄₅H₆₆N₂O₆S: C, 70.77; H, 8.65; N, 3.60. Found: C, 70.68; H, 9.0; N, 3.65

### (4) Synthesis of 3,5-Didecyloxybenzyl 4-(1-Phenyl-C61)butyrate

In a 20-ml eggplant flask was placed 49 mg (0.060 mmol) of 3,5-didecyloxybenzyl 5-(2-tosylhydrazono)-5-phenylpentanoate. After purging the flask with nitrogen, 1.0 ml of pyridine was added, the mixture was stirred at room temperature for 10 minutes and combined with 3.8 mg (0.070 mmol) of sodium methoxide, and stirred for further 30 minutes. A solution of 39 mg (0.050 mmol) of C₆₀ in 2.0 ml of o-dichlorobenzene was slowly added, followed by stirring at 80° C. for 24 hours. The reaction mixture was directly purified by silica gel column chromatography (hexane to hexane/AcOEt=95:5). The resulting solid was dissolved in toluene, subjected to isomerization by refluxing for 24 hours, and thereby yielded 26 mg of the target compound in a yield of 40%.

¹H NMR (CDCl₃, 200 MHz): 7.92 (d, 2H, J=6.4 Hz), 7.56-7.44 (m, 3H), 6.44 (s, 2H), 6.36 (s, 1H), 5.01 (s, 2H), 3.89 (t, 4H, J=6.4 Hz), 2.91 (t, 2H, J=8.0 Hz), 2.58 (t, 2H, J=7.4 Hz), 2.23-2.15 (m, 2H), 1.78 (m, 4H), 1.26 (m, 28H), 0.87 (t, 6H, J=6.0 Hz).

¹³C NMR (CDCl₃, 50.3 MHz): 14.38, 20.07, 22.88, 26.28, 29.50, 29.58, 29.74, 31.38, 32.05, 34.23, 35.37, 38.25, 38.81, 60.95, 66.29, 68.06, 79.80, 100.75, 106.24, 127.52, 128.44, 130.49, 131.83, 134.78, 136.44, 137.54, 138.03, 139.49, 141.00, 141.62, 141.81, 142.16, 142.71, 143.42, 144.84, 145.49, 146.10, 147.07, 151.09, 160.07, 172.29, 185.38. MALDI-TOF MS: m/z 1297.6, LC-MS: 1299.25. IR (KBr): 3855, 2919, 2848, 1734, 1595, 1458, 1162, 1063, 832, 698 cm⁻¹. Anal. Calcd. for C₉₈H₅₈O₄: C, 90.6; H, 4.46. Found C, 89.35; H, 4.58. UV (CHCl₃)=6.16×10⁻⁶ M 328 nm (ε₃₂₈=3.83×10⁴), 260 nm (ε₂₆₀=8.34×10⁴).

### Example 2

### Solar Battery Cell Including 3,5-Didecyloxybenzyl 4-(1-Phenyl-C61)butyrate and P3HT

A solar battery cell was prepared by dissolving 15 mg of P3HT and 15 mg of 3,5-didecyloxybenzyl 4-(1-phenyl-C61)butyrate in 1.0 ml of o-dichlorobenzene to give a solution; applying the solution via spin coating at a number of revolutions of 2000 rpm to give a film; and heating the coated film at 100° C. for 30 minutes. The properties of the cell were measured and found to be as follows:

E_{ff}=0.16%, FF=0.37, V_{oc}=0.19 V, I_{sc}=2.28 mA/cm²

### Example 3

### Synthesis of 4-[(3,4-Dioctyloxyphenyl)-C61]butoxy]benzene-1,2-dinitrile

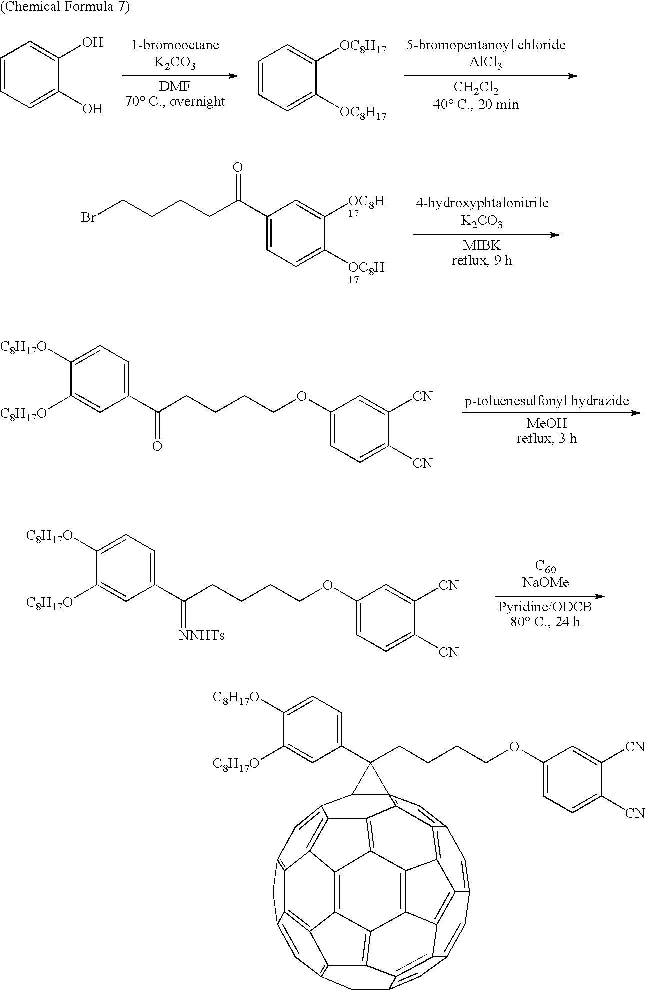

### (1) Synthesis of 1,2-Dioctyloxybenzene

In a 20-ml eggplant flask were placed 501 mg (3.63 mmol) of potassium carbonate and 100 mg (0.908 mmol) of catechol. After purging the flask with nitrogen, and 5.0 ml of DMF was added, followed by stirring at 70° C. for 20 minutes. The mixture was allowed to cool to room temperature and combined with 0.33 ml (1.91 mmol) of 1-bromooctane, followed by stirring at 70° C. for 12 hours. Insoluble components were removed by filtration through Celite, and the solvent was distilled off on a rotary evaporator to give a crude product. The crude product was purified by silica gel column chromatography (hexane/AcOEt=90/10) and thereby yielded 161 mg of the target compound in a yield of 53%.

¹H NMR (CDCl₃, 200 MHz): δ 6.86 (s, 4H), 3.97 (t, 4H, J=5.6 Hz), 1.87-1.73 (m, 4H) 1.47-1.28 (m, 20H), 0.90 (t, 6H, J=6.2 Hz).

### (2) Synthesis of 5-Bromo-1-(3,4-dioctyloxyphenyl)pentan-1-one

In a 50-ml eggplant flask was placed 537 mg (2.69 mmol) of 5-bromopentanoyl chloride, and 7.0 ml of dichloromethane was added to give a solution. Next, 398 mg (2.99 mmol) of aluminum trichloride was added to the ice-cooled solution, and a solution of 1.00 g (2.99 mmol) of 1,2-dioctyloxybenzene in 3.0 ml of dichloromethane was slowly added. The mixture was stirred while ice-cooling for 45 minutes, followed by stirring at 40° C. for further 20 minutes. The reaction mixture was allowed to cool to room temperature, from which the solvent was distilled off on a rotary evaporator. The resulting crude product was purified by silica gel column chromatography (hexane/AcOEt=90/10) and thereby yielded 1.34 g of the target compound in a yield of 86%.

¹H NMR (CDCl₃, 200 MHz): δ 7.55-7.50 (m, 2H), 6.87 (d, J=7.8, 1H), 4.08-4.04 (m, 4H), 3.47 (t, J=12, 2H), 2.98 (t, J=13.6, 2H), 2.02-1.75 (m, 8H), 1.56-1.28 (m, 20H), 0.88 (t, J=7.0, 6H). ¹³C (CDCl₃, 50.3 MHz): 197.74, 153.17, 148.56, 129.57, 122.34, 112.21, 111.41, 69.22, 37.00, 33.48, 32.40, 31.92, 29.48, 29.14, 29.37, 26.14, 23.28, 22.81, 14.27.

Anal. Calcd. For C₂₇H₄₅BrO₃: C, 65.19; H, 9.05. Found: C, 65.09; H, 9.02. IR (KBr): 3073, 3055, 3036, 2923, 2853, 2604, 2312, 2062, 1928, 1845, 1670, 1584, 1514, 1499, 1472, 1429, 1394, 1334, 1294, 1269, 1230, 1173, 1145, 1094, 1081, 1060, 1035, 1014, 991, 918, 878, 816, 800, 627 cm⁻¹. MS (EI) m/z 498.

### (3) Synthesis of 4-[5-(3,4-Dioctyloxyphenyl)-5-oxopentyloxy]benzene-1,2-dicarbonitrile

In a 100-ml eggplant flask were placed 1.00 g (2.01 mmol) of 5-bromo-1-(3,4-dioctyloxyphenyl)pentan-1-one, 264 mg (1.83 mmol) of 4-hydroxyphthalonitrile, and 759 mg (5.49 mmol) of potassium carbonate. After purging the flask with nitrogen, and 25.0 ml of methyl iso-butyl ketone was added, followed by heating under reflux for 12 hours. The reaction mixture was allowed to cool to room temperature, filtrated through Celite to remove insoluble matter, and the filtrate was diluted with methylene chloride and washed with water. The organic phase was dried over sodium sulfate, from which sodium sulfate was removed by filtration, and the solvent was distilled off on a rotary evaporator. The resulting crude product was purified by silica gel chromatography (hexane/AcOEt=70/30) and thereby yielded 759 mg of the target compound in a yield of 74%.

¹H NMR (CDCl₃, 200 MHz) δ 7.69 (d, J=8.6, 1H), 7.54 (d, J=9.8, 2H), 7.24-7.11 (m, 2H), 6.87 (d, J=8.2, 1H), 4.08 (m, 6H), 3.0 (br, 2H), 1.91-1.75 (m, 8H), 1.59-1.28 (m, 20H), 0.90 (t, J=10.8, 6H). ¹³C NMR (CDCl₃, 50.3 MHz) 197.63, 161.67, 153.27, 148.56, 134.86, 129.52, 122.34, 119.33, 119.04, 117.11, 115.48, 115.05, 112.25, 111.43, 106.84, 69.26, 37.31, 31.88, 29.43, 29.41, 29.34, 29.28, 29.15, 28.47, 26.10, 22.76, 20.89, 14.22. IR (KBr): 3082, 2952, 2231, 1670, 1592, 1520, 1465, 1380, 1346, 1270, 1188, 1129, 1098, 1018, 969, 879, 837, 818 cm⁻¹.

Anal. Calcd. For C₃₅H₄₈N₂O₄: C, 74.96; H, 8.63; N, 5.00. Found: C, 74.86; H, 8.76; N, 4.93. MS (EI) m/z 560.

### (4) Synthesis of 4-[5-(3,4-Dioctyloxyphenyl)-5-tosylhydrazonopentyloxy]benzene-1,2-dicarbonitrile

In a 10-ml eggplant flask were placed 50 mg (0.089 mmol) of 4-[5-(3,4-dioctyloxyphenyl)-5-oxopentyloxy]benzene-1,2-dicarbonitrile and 50.5 mg (0.271 mmol) of p-tolylsulfonylhydrazide, and 3.0 ml of MeOH was added to give a solution. The solution was heated under reflux for 4 hours, followed by stirring at room temperature for 12 hours. The solvent was distilled off on a rotary evaporator, the resulting crude product was purified by silica gel column chromatography (hexane/AcOEt=75/25) and thereby yielded 53 mg of the target compound in a yield of 81%.

¹H NMR (CDCl₃, 200 MHz): δ 8.47 (s, 1H), 7.91 (d, J=8.2, 2H), 7.63 (d, J=8.6, 1H), 7.31-7.03 (m, 6H), 6.79 (d, J=8.4, 1H), 4.03-3.93 (m, 6H), 2.69 (br, 2H), 2.41 (s, 3H), 1.89-1.65 (m, 8H), 1.49-1.21 (m, 20H), 0.91 (t, J=12.6, 6H).

¹³C NMR (CDCl₃, 50.3 MHz): δ 161.66, 156.80, 148.56, 143.94, 135.20, 134.91, 129.67, 129.31, 124.15, 122.38, 119.45, 117.12, 117.03, 115.51, 115.08, 113.67, 112.26, 106.89, 69.55, 68.70, 37.53, 31.93, 31.90, 29.54, 29.36, 29.28, 26.54, 22.79, 21.76, 14.26. IR (KBr): 3214, 2921, 2853, 2232, 1600, 1564, 1520, 1488, 1472, 1374, 1327 cm⁻¹. Anal. Calcd. For C₄₂H₅₆N₄O₅S: C, 69.20; H, 7.74; N, 7.69. Found: C, 69.11; H, 7.97; N, 7.63. MS (EI) m/z 728

### (5) Synthesis of 4-{4-[(3,4-Dioctyloxyphenyl)-C61]butoxy}benzene-1,2-dicarbonitrile

In a 20-ml eggplant flask was placed 49 mg (0.067 mmol) of 4-[5-(3,4-dioctyloxyphenyl)-5-tosylhydrazonopentyloxy]benzene-1,2-dicarbonitrile. After purging the flask with nitrogen, the mixture was combined with 1.0 ml of pyridine, stirred at room temperature for 10 minutes, and further combined with 3.6 mg (0.067 mmol) of sodium methoxide, and stirred for further 30 minutes.

A solution of 44 mg (0.060 mmol) of C₆₀ in 5.0 ml of o-dichlorobenzene was slowly added, followed by stirring at 80° C. for 24 hours. The reaction mixture was directly purified by silica gel column chromatography (hexane/AcOEt=85:15). The resulting solid was dissolved in toluene, subjected to isomerization by refluxing for 24 hours, and thereby yielded 25 mg of the target compound in a yield of 33%.

¹H NMR (CDCl₃, 200 MHz): δ 7.70 (d, J=8.8, 1H), 7.4 (d, J=7.4, 1H), 7.24 (s, 1H), 7.17 (d, J=11.4, 2H), 6.97 (d, J=8.0, 1H), 4.08 (m, 6H), 2.9 (br, 2H), 1.92 (m, 8H), 1.29 (m, 20H), 0.89 (t, J=5.0, 6H). ¹³C (CDCl₃, 50.3 MHz): δ 161.65, 148.98, 148.78, 148.50, 147.99, 147.62, 146.88, 145.51, 144.86, 144.48, 144.19, 143.98, 143.69, 143.49, 143.31, 142.77, 142.44, 142.10, 141.85, 141.55, 141.34, 141.00, 140.71, 140.14, 139.92, 139.21, 138.77, 138.54, 137.61, 134.93, 128.52, 125.07, 123.77, 119.37, 119.09, 117.25, 117.06, 115.47, 115.03, 112.85, 107.02, 80.26, 69.77, 69.12, 68.80, 68.55, 60.79, 51.91, 35.50, 31.98, 29.46, 28.67, 26.32, 23.67, 22.86, 20.86, 14.34. Anal. Calcd. for C₉₅H₄₈N₂O₃: C, 90.17; H, 3.82; N, 2.21. Found: C, 90.03; H, 3.92; N, 2.28. MALDI-TOF MS: m/z 1264. UV-Vis (CH₂Cl₂) (conc 4.74×10⁻⁵ M) λₘₐₓ 327, 259 nm.

### Example 4

Solar Battery Cell Including 4-{4-[(3,4-Dioctyloxyphenyl)-C61]butoxy}benzene-1,2-dicarbonitrile and P3HT

A solar battery cell was prepared by dissolving 15 mg of P3HT and 15 mg of 4-{4-[(3,4-Dioctyloxyphenyl)-C61]butoxy}benzene-1,2-dicarbonitrile in 1.0 ml of o-dichlorobenzene to give a solution; applying the solution via spin coating at a number of revolutions of 2000 rpm to give a film; and heating the coated film at 100° C. for 30 minutes. The properties of the cell were measured and found to be as follows:

E_{ff}=0.17%, FF=0.40, V_{oc}=0.33 V, I_{sc}=1.31 mA/cm²

Independently, another cell was prepared by applying the above-prepared solution via spin coating at a number of revolutions of 2000 rpm to give a film; and heating the coated film at 150° C. for 5 hours. The properties of the cell were measured and found to be as follows:

E_{ff}=0.24%, FF=0.39, V_{oc}=0.35 V, I_{sc}=1.74 mA/cm²

### Example 5

### Synthesis of 1-(3,4-Dioctyloxyphenyl)-1-(1-phenoxybutyl)-C61

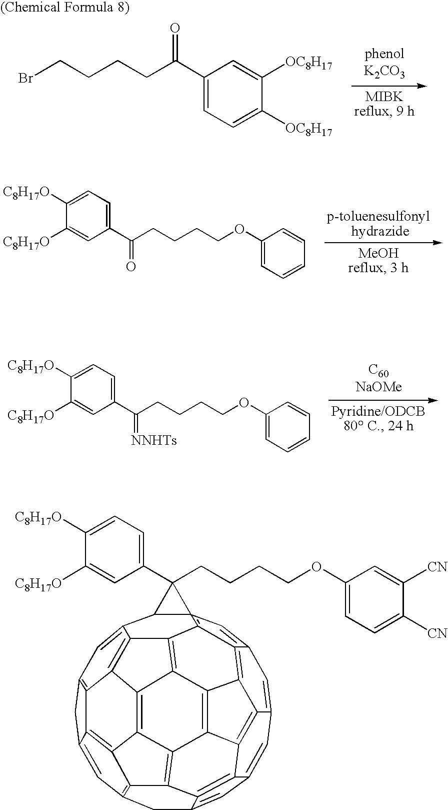

### (1) Synthesis of 1-(3,4-Dioctyloxyphenyl)-5-phenoxypentan-1-one

In a 30-ml eggplant flask were placed 116 mg (0.234 mmol) of 5-bromo-1-(3,4-dioctyloxyphenyl)pentan-1-one, 20.0 mg (0.213 mmol) of phenol, and 88.1 mg (0.637 mmol) of potassium carbonate. After purging the flask with nitrogen, 5.0 ml of methyl iso-butyl ketone was added, followed by heating under reflux for 12 hours. The reaction mixture was allowed to cool to room temperature, filtrated through Celite to remove insoluble matter, and the filtrate was diluted with methylene chloride and washed with water. The organic phase was dried over sodium sulfate, from which sodium sulfate was removed by filtration, and the solvent was distilled off on a rotary evaporator. The resulting crude product was purified by silica gel chromatography (hexane/AcOEt=85/15) and thereby yielded 83 mg of the target compound in a yield of 76%.

¹H NMR (CDCl₃, 200 MHz): 7.56 (d, J=10.8, 2H), 7.29 (d, J=8.8, 2H), 6.94-6.82 (m, 4H), 4.07 (m, 6H), 3.02 (t, J=12, 2H), 1.91-1.78 (m, 8H), 1.54-1.28 (m, 20H), 0.90 (t, J=11.2, 6H). ¹³C (CDCl₃, 50.3 MHz): 198.19, 158.61, 153.11, 148.57, 129.77, 129.14, 122.38, 120.32, 114.28, 112.30, 111.47, 69.22, 67.47, 37.69, 31.92, 29.48, 29.45, 29.39, 29.31, 29.19, 29.01, 26.14, 22.81, 21.46, 14.27. IR (KBr): 3073, 3055, 3036, 2923, 2853, 2604, 2312, 2062, 1928, 1845, 1670, 1584, 1514, 1499, 1472, 1429, 1394, 1334, 1294, 1269, 1230, 1173, 1145, 1094, 1081, 1060, 1035, 1014, 991, 918, 878, 816, 800, 627.

Anal. Calcd. for C₃₃H₅₀O₄: C, 77.60, H, 9.87. Found: C, 77.53; H, 10.09. MS (EI) m/z 510.

### (2) Synthesis of 1-(3,4-Dioctyloxyphenyl)-5-phenoxypentan-1-one Tosylhydrazone

In a 10-ml eggplant flask were placed 324 mg (0.634 mmol) of 1-(3,4-dioctyloxyphenyl)-5-phenoxypentan-1-one and 360 mg (1.93 mmol) of p-tolylsulfonylhydrazide, and 10 ml of MeOH was added to give a solution. The solution was heated under reflux for 4 hours, followed by stirring at room temperature for 12 hours. The solvent was distilled off on a rotary evaporator, and the resulting crude product was purified by silica gel column chromatography (hexane/AcOEt=60/40) and thereby yielded 306 mg of the target compound in a yield of 71%.

¹H NMR (CDCl₃, 200 MHz): 7.97 (s, 1H), 7.89 (d, J=8.2, 2H), 7.27 (d, J=6.8, 2H), 7.09-7.05 (d, J=8.0, 2H), 7.04-6.84 (m, 4H), 6.77 (d, J=8.6, 2H), 3.97 (t, J=11.4, 6H), 2.67 (t, J=7.2, 2H), 2.38 (s, 3H), 1.79-1.67 (m, 8H), 1.28 (m, 20H), 0.90 (t, J=11.2, 6H);

¹³C (CDCl₃, 50.3 MHz): 158.61, 158.26, 148.60, 143.67, 143.59, 135.32, 129.73, 129.29, 127.72, 124.45, 120.84, 120.39, 114.40, 114.32, 114.24, 69.48, 31.97, 29.60, 29.51, 29.43, 29.34, 29.23, 26.30, 23.51, 21.79, 21.51, 14.32. IR (KBr): 3228, 2923, 2852, 1670, 1600, 1520, 1497, 1474, 1425, 1398, 1351, 1248, 1214, 1168, 1148, 1077, 1032, 888, 801, 752, 723, 691, 668, 612 cm⁻¹. Anal. Calcd. for C₄₀H₅₈N₂O₅S: C, 70.76; H, 8.61; N, 4.13. Found: C, 70.85; H, 8.69; N, 4.05. MS (EI) m/z 679 (M⁺).

### (3) Synthesis of 1-(3,4-Dioctyloxyphenyl)-1-(1-phenoxybutyl)-C61

In a 20-ml eggplant flask was placed 134 mg (0.197 mmol) of 1-(3,4-dioctyloxyphenyl)-5-phenoxypentan-1-one tosylhydrazone. After purging the flask with nitrogen, 1.0 ml of pyridine was added, the mixture was stirred at room temperature for 10 minutes, combined with 10.7 mg (0.197 mmol) of sodium methoxide, and stirred for further 30 minutes. A solution of 128 mg (0.177 mmol) of C₆₀ in 5.0 ml of o-dichlorobenzene was slowly added, followed by stirring at 80° C. for 24 hours. The reaction mixture was directly purified by silica gel column chromatography (hexane/AcOEt=85:15). The resulting solid was dissolved in toluene, subjected to isomerization by refluxing for 24 hours, and thereby yielded 69 mg of the target compound in a yield of 32%.

¹H NMR (CDCl₃, 200 MHz): 7.41 (d, J=7.4, 3H), 7.24 (s, 1H), 7.00-6.85 (m, 4H), 4.07 (t, J=6.8, 6H), 2.92 (br, 2H), 2.02-1.84 (m, 8H), 1.55-1.29 (m, 20H), 0.89 (t, J=5.2, 6H). MALDI-TOF MS: m/z 1213. UV-Vis (CH₂Cl₂) (conc 1.18×10⁻⁵ M) 327 nm (ε₃₂₇=0.2×10⁴), 259 nm (ε₂₅₉=0.72×10⁴)

### Example 6

### Solar Battery Cell Including 1-(3,4-Dioctyloxyphenyl)-1-(1-phenoxybutyl)-C61 and P3HT

A solar battery cell was prepared by dissolving 15 mg of P3HT and 15 mg of 1-(3,4-dioctyloxyphenyl)-1-(1-phenoxybutyl)-C61 in 1.0 ml of o-dichlorobenzene to give a solution; applying the solution via spin coating at a number of revolutions of 2000 rpm to give a film; and heating the coated film at 100° C. for 30 minutes. The properties of the cell were measured and found to be as follows:

E_{ff}=0.094%, FF=0.37, V_{oc}=0.27 V, I_{sc}=0.95 mA/cm²

### Example 7

### Synthesis of 1-(3,4-Dioctyloxyphenyl)-1-[4-(4-iodophenoxy)butyl]C61

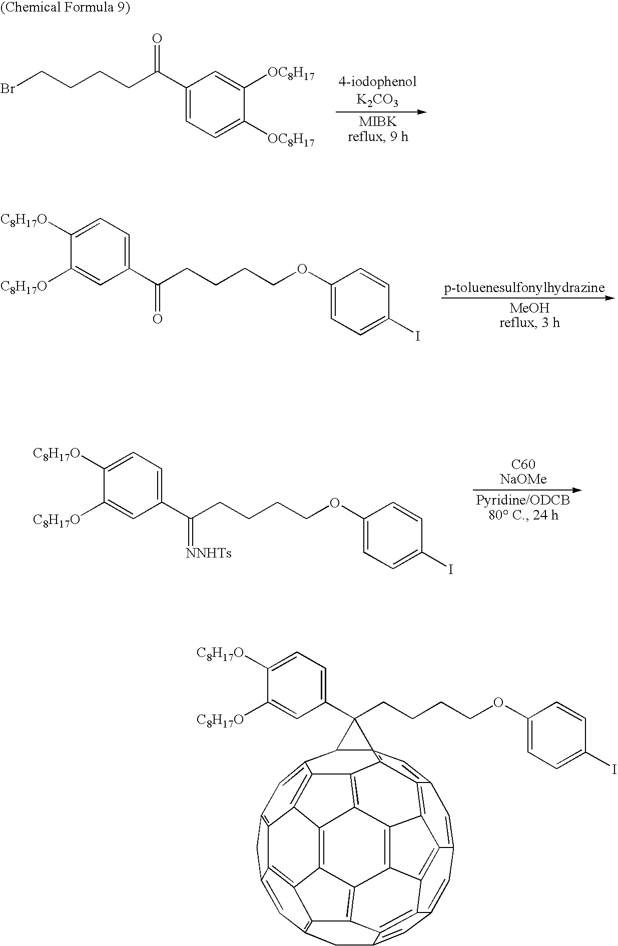

### (1) Synthesis of 1-(3,4-Dioctyloxyphenyl)-5-(4-iodophenoxy)pentan-1-one

In a 30-ml eggplant flask were placed 219 mg (0.440 mmol) of 5-bromo-1-(3,4-dioctyloxyphenyl)pentan-1-one, 88.0 mg (0.400 mmol) of 4-iodophenol, and 166 mg (1.20 mmol) of potassium carbonate. After purging the flask with nitrogen, 10 ml of methyl iso-butyl ketone was added, followed by heating under reflux for 12 hours. The reaction mixture was allowed to cool to room temperature, filtrated through Celite to remove insoluble matter, and the filtrate was diluted with methylene chloride and washed with water. The organic phase was dried over sodium sulfate, from which sodium sulfate was removed by filtration, and the solvent was distilled off on a rotary evaporator. The resulting crude product was purified by silica gel chromatography (hexane/AcOEt=90/10) and thereby yielded 199 mg of the target compound in a yield of 78%.

¹H NMR (CDCl₃, 200 MHz): 7.54 (d, J=14, 4H), 6.85 (d, J=8.0, 1H), 6.66 (d, J=9.0, 2H), 4.04 (m, 6H), 2.97 (t, J=13.6, 2H), 1.92-1.75 (m, 8H), 1.50-1.21 (m, 20H), 0.91 (t, J=13.0, 6H). ¹³C (CDCl₃, 50.3 MHz): 198.26, 158.48, 153.17, 148.57, 137.87, 129.68, 122.42, 117.74, 116.71, 112.28, 111.46, 82.48, 69.26, 67.74, 37.64, 31.95, 29.50, 29.41, 29.31, 29.20, 26.16, 22.83, 21.36, 14.30. FT-IR(KBr): 2920, 2851, 1667, 1583, 1486, 1468, 1389, 1283, 1249, 1174, 1150, 1102, 1060, 963, 821, 794, 634. MS (EI) m/z 636.

### (2) Synthesis of 1-(3,4-Dioctyloxyphenyl)-5-(4-iodophenoxy)pentan-1-one Tosylhydrazone

In a 10-ml eggplant flask were placed 165 mg (0.273 mmol) of 1-(3,4-dioctyloxyphenyl)-5-(4-iodophenoxy)pentan-1-one and 155 mg (0.832 mmol) of p-tolylsulfonylhydrazide, and 5.0 ml of MeOH was added to give a solution. The solution was heated under reflux for 4 hours, followed by stirring at room temperature for 12 hours. The solvent was distilled off on a rotary evaporator, and the resulting crude product was purified by silica gel column chromatography (hexane/AcOEt=80/20) and thereby yielded 160 mg of the target compound in a yield of 73%.

¹H NMR (CDCl₃, 200 MHz): 8.05 (s, 1H), 7.89 (d, J=8.2, 2H), 7.53 (d, J=9.0, 2H), 7.27 (d, J=7.4, 3H), 7.08 (d, J=8.4, 1H), 6.76 (d, J=8.4, 1H) 6.67 (d, J=9.0, 2H), 4.01-3.83 (m, 6H), 2.65 (t, 2H), 2.38 (s, 3H), 1.83-1.63 (m, 8H), 1.29 (m, 20H), 0.91 (t, J=11.8, 6H);

¹³C(CDCl₃, 50.3 MHz) 158.46, 158.20, 155.40, 150.49, 148.54, 143.57, 137.94, 135.20, 129.25, 127.69, 124.33, 116.74, 113.66, 82.88, 69.47, 67.74, 37.74, 31.98, 31.95, 29.58, 29.46, 29.41, 29.31, 26.42, 23.20, 22.71, 21.78, 14.31. IR(KBr): 3244, 2920, 2852, 1732, 1585, 1516, 1487, 1469, 1426, 1407, 1351, 1220, 1078, 1021, 912, 870, 802, 720, 668, 610. MS (EI) m/z 804. Anal. Calcd. for C₄₀H₅₇IN₂O₅S: C, 59.69; H, 7.14; N, 3.48. Found: C, 59.61; H, 7.43; N, 3.44.

### (3) Synthesis of 1-(3,4-Dioctyloxyphenyl)-1-[4-(4-iodophenoxy)butyl]C61

In a 20-ml eggplant flask was placed 125 mg (0.162 mmol) of 1-(3,4-dioctyloxyphenyl)-5-(4-iodophenoxy)pentan-1-one tosylhydrazone. After purging the flask with nitrogen, 1.0 ml of pyridine was added, the mixture was stirred at room temperature for 10 minutes, combined with 10.7 mg (0.197 mmol) of sodium methoxide, and stirred for further 30 minutes. A solution of 105 mg (0.146 mmol) of C₆₀ in 5.0 ml of o-dichlorobenzene was slowly added, followed by stirring at 80° C. for 24 hours. The reaction mixture was directly purified by silica gel column chromatography (hexane/AcOEt=85:15). The resulting solid was dissolved in toluene, subjected to isomerization by refluxing for 24 hours, and thereby yielded 59 mg of the target compound in a yield of 30%.

¹H NMR (CDCl₃, 200 MHz): 7.43-7.28 (m, 4H), 6.94 (d, J=8.2, 1H), 6.53 (d, J=9.0, 2H), 4.02 (m, 6H), 2.82 (br, 2H), 1.75 (m, 8H), 1.49-1.22 (m, 20H), 0.82 (t, J=4.0, 6H). ¹³C (CDCl₃, 50.3 MHz): 158.50, 148.84, 148.67, 147.95, 147.72, 145.53, 144.84, 144.73, 144.47, 144.42, 144.33, 144.15, 144.00, 143.66, 143.45, 142.69, 142.60, 141.94, 141.81, 140.62, 140.39, 137.63, 137.47, 128.74, 125.05, 118.14, 116.77, 112.59, 82.72, 80.40, 69.74, 69.06, 67.59, 52.22 , 33.94, 32.00, 29.66, 29.60, 29.46, 29.10, 26.32, 26.23, 23.87, 22.88, 14.38. IR(KBr): 2921, 1719, 1510, 1561, 1466, 1243, 816. MALDI-TOF MS: m/z 1340.

Anal. Calcd. For C₉₃H₄₉IO₃: C, 83.28; H, 3.68. Found: C, 82.93; H, 3.57. UV-Vis (CHCl₃) (conc 3.73×10⁻⁶ M) 327 mm (ε₃₂₇=2.8×10⁴), 430 nm (ε₄₃₀=2×10⁴). Fluorescence (CHCl₃) 349 nm, intensity=2.47838 (conc=3.73×10⁻⁶ M) with 260 nm excitation

### Example 8

### Solar Battery Cell Including 4-{1-(3,4-Dioctyloxyphenyl)-C61}-1-(4-iodophenoxy)butane and P3HT

A solar battery cell was prepared by dissolving 15 mg of P3HT and 15 mg of 1-(3,4-dioctyloxyphenyl)-1-[4-(4-iodophenoxy)butyl]C61 in 1.0 ml of o-dichlorobenzene to give a solution; applying the solution via spin coating at a number of revolutions of 2000 rpm to give a film; and heating the coated film at 100° C. for 30 minutes. The properties of the cell were measured and found to be as follows:

E_{ff}=0.15%, FF=0.32, V_{oc}=0.26 V, I_{sc}=1.87 mA/cm²

Independently, another cell was prepared by applying the above-prepared solution via spin coating at a number of revolutions of 2000 rpm to give a film; and heating the coated film at 150° C. for 5 hours. The properties of the cell were measured and found to be as follows:

E_{ff}=0.25%, FF=0.38, V_{oc}=0.25 V, I_{sc}=2.68 mA/cm²

### Example 9

### Synthesis of 1-(3,4-Dioctyloxyphenyl)-1-[4-(2,3,4,5,6-pentafluorophenoxy)butyl]C61

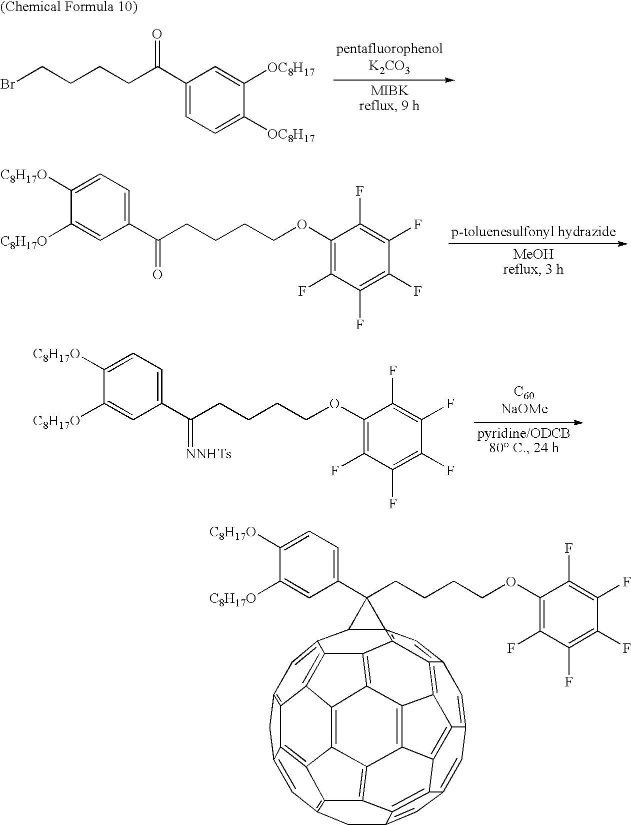

### (1) Synthesis of 1-(3,4-Dioctyloxyphenyl)-5-(2,3,4,5,6-pentafluorophenoxy)pentan-1-one

In a 30-ml eggplant flask were placed 297 mg (0.597 mmol) of 5-bromo-1-(3,4-dioctyloxyphenyl)pentan-1-one, 100 mg (0.540 mmol) of pentafluorophenol, and 225 mg (1.63 mmol) of potassium carbonate. After purging the flask with nitrogen, 7.0 ml of methyl iso-butyl ketone was added, followed by heating under reflux for 7 hours. The reaction mixture was allowed to cool to room temperature, filtrated through Celite to remove insoluble matter, and the filtrate was diluted with methylene chloride and washed with water. The organic phase was dried over sodium sulfate, from which sodium sulfate was removed by filtration, and the solvent was distilled off on a rotary evaporator. The resulting crude product was purified by silica gel chromatography (hexane/AcOEt=85/15) and thereby yielded 282 mg of the target compound in a yield of 87%.

¹H NMR (CDCl₃, 200 MHz): 7.56 (d, J=10.0, 2H), 6.87 (d, J=7.8, 1H), 4.22 (t, J=9.8, 2H), 4.01 (m, 4H), 3.03 (t, J=10.8, 2H), 1.94-1.77 (m, 8H), 1.46-1.28 (m, 20H), 0.91 (t, J=6.2, 6H). ¹⁹F (CDCl₃, 188 MHz): −155.92 (dd, 2F), −162.40-162.98 (m, 3F). ¹³C (CDCl₃, 50.3 MHz): 197.88, 153.18, 148.59, 129.64, 122.35, 120.77, 112.21, 111.42, 69.24, 69.02, 37.45, 31.95, 29.42, 29.32, 29.20, 26.16, 22.83, 20.86, 14.27. EI-MS: m/z 600. Anal. Calcd for C₃₃H₄₅F₅O₄: C, 65.98; H, 7.55. Found: C, 66.05; H, 7.63.

### (2) Synthesis of 1-(3,4-Dioctyloxyphenyl)-5-(2,3,4,5,6-pentafluorophenoxy)pentan-1-one tosylhydrazone

In a 10-ml eggplant flask were placed 360 mg (0.399 mmol) of 1-(3,4-dioctyloxyphenyl)-5-(2,3,4,5,6-pentafluorophenoxy)pentan-1-one and 340 mg (1.83 mmol) of p-tolylsulfonylhydrazide, and 10 ml of MeOH was added to give a solution. The solution was heated under reflux for 5 hours, followed by stirring at room temperature for 12 hours. The solvent was distilled off on a rotary evaporator, and the resulting crude product was purified by silica gel column chromatography (hexane/AcOEt=75/25) and thereby yielded 273 mg of the target compound in a yield of 89%.

¹H NMR (CDCl₃, 200 MHz): 8.35 (s, 1H), 7.92 (d, J=8.5, 2H), 7.31 (d, J=10.8, 3H), 7.08 (d, J=10, 1H), 6.79 (d, J=8.6, 1H), 4.10 (t, J=10, 2H), 4.00 (m, 4H), 2.68 (t, J=8, 2H), 2.40 (s, 1H), 1.82-1.77 (m, 8H), 1.44-1.29 (m, 20H), 0.89 (t, J=6.6, 6H);

¹⁹F (CDCl₃, 188 MHz): −155.75-156.19 (m, 2F), −162.21-162.85 (m, 3F). ¹³C (CDCl₃, 50.3 MHz): 157.15, 155.34, 150.47, 149.97, 149.51, 148.53, 143.73, 143.61, 135.17, 129.22, 127.65, 124.32, 119.33, 113.67, 111.68, 69.43, 69.01, 37.43, 31.92, 29.54, 29.46, 29.43, 29.38, 29.16, 26.24, 22.80, 21.67, 14.24 EI-MS: m/z 768.

Anal. Calcd. for C₄₀H₅₃F₅N₂O₅S: C, 62.48; H, 6.95; N, 3.64. Found: C, 62.42; H, 7.06; N, 3.61.

### (3) Synthesis of 1-(3,4-Dioctyloxyphenyl)-1-[4-(2,3,4,5,6-pentafluorophenoxy)butyl]C61

In a 20-ml eggplant flask was placed 246 mg (0.319 mmol) of 1-(3,4-dioctyloxyphenyl)-5-(2,3,4,5,6-pentafluorophenoxy)pentan-1-one tosylhydrazone. After purging the flask with nitrogen, 1.0 ml of pyridine was added, the mixture was stirred at room temperature for 10 minutes, combined with 17.3 mg (0.319 mmol) of sodium methoxide, and stirred for further 30 minutes. A solution of 207 mg (0.288 mmol) of C₆₀ in 1.0 ml of o-dichlorobenzene was slowly added, followed by stirring at 80° C. for 24 hours. The reaction mixture was directly purified by silica gel column chromatography (hexane/AcOEt=90:10). The resulting solid was dissolved in toluene, subjected to isomerization by refluxing for 24 hours, and thereby yielded 150 mg of the target compound in a yield of 36%.

¹H NMR (CDCl₃, 200 MHz): 7.56 (d, 2H), 6.87 (d, J=8, 1H), 4.22 (t, 2H), 4.08-3.96 (m, 4H), 3.03 (t, 2H), 1.94-1.77 (m, 8H), 1.46-1.28 (m, 20H), 0.88 (t, J=6, 6H). ¹⁹F(CDCl₃, 188 MHz): −156.31 (dd, 2F), −162.83-163.59 (m, 3F). ¹³C (CDCl₃, 50.3 MHz): 197.90, 153.19, 148.89, 148.60, 148.01, 147.72, 145.58, 144.84, 144.71, 144.49, 144.31, 144.16, 143.68, 143.46, 142.71, 142.57, 141.94, 141.80, 140.64, 140.40, 140.20, 139.14, 137.66, 137.51, 135.21, 130.62, 129.66, 128.61, 125.03, 122.37, 118.10, 112.63, 111.44, 80.35, 69.70, 69.04, 52.05, 37.46, 34.06, 31.96, 29.97, 29.85, 29.59, 29.21, 26.31, 23.47, 22.85, 20.86, 14.30. MALDI-TOF MS: m/z 1303. Anal. Calcd. for C₉₃H₄₅F₅O₃: C, 85.57; H, 3.47. Found: C, 84.97; H, 3.39. UV-Vis (CHCl₃) (conc 3.83×10⁻⁶ M) 397 nm (ε₃₉₇=2×10⁴), 327 nm (ε₃₂₇=5×10⁴), 259 nm (ε₂₅₉=0.12×10⁴)

### Example 10

### Solar Battery Cell Including 1-(3,4-Dioctyloxyphenyl)-1-[4-(2,3,4,5,6-pentafluorophenoxy)butyl]C61 and P3HT

A solar battery cell was prepared by dissolving 15 mg of P3HT and 15 mg of 1-(3,4-dioctyloxyphenyl)-1-[4-(2,3,4,5,6-pentafluorophenoxy)butyl]C61 in 1.0 ml of o-dichlorobenzene to give a solution; applying the solution via spin coating at a number of revolutions of 2000 rpm to give a film; and heating the coated film at 150° C. for 10 hours. The properties of the cell were measured and found to be as follows:

E_{ff}=0.028%, FF=0.38, V_{oc}=0.16 V, I_{sc}=0.46 mA/cm²

### Example 11

### Synthesis of Methyl 4-[1-(3,4-dioctyloxyphenyl)-C61]benzoate

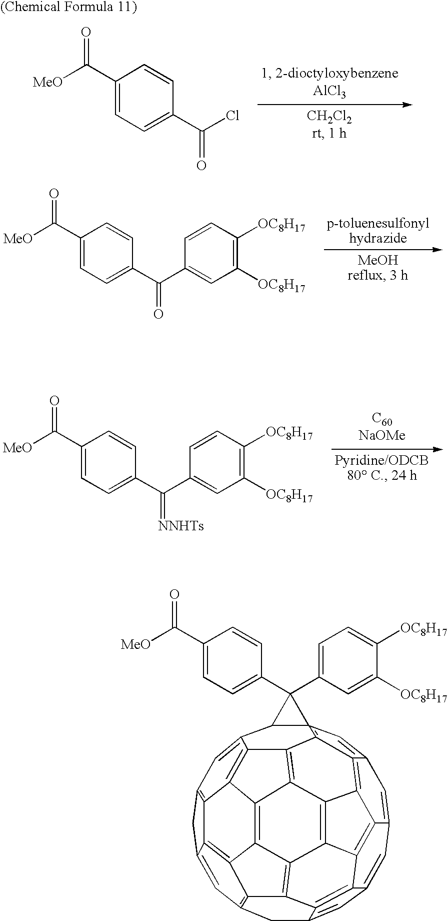

(1) Synthesis of Methyl 4-(3,4-Dioctyloxybenzoyl)benzoate

In a 30-ml eggplant flask was placed 268 mg (1.35 mmol) of methyl 4-(chlorocarbonyl)benzoate. After purging the flask with nitrogen, 6.0 ml of dichloromethane was added to give a solution, the solution was ice-cooled, combined with 199 mg (1.49 mmol) of aluminum trichloride, and stirred under ice-cooling for 20 minutes. A solution of 500 mg (1.49 mmol) of 1,2-dioctyloxybenzene in 4.0 ml of dichloromethane was slowly added, and the mixture was stirred at room temperature for 1 hour, followed by stirring at 40° C. for further 2 hours. The solvent was distilled off on a rotary evaporator, and the resulting crude product was purified by silica gel column chromatography (hexane/AcOEt=90/10) and thereby yielded 624 mg of the target compound in a yield of 93%.

¹H NMR (CDCl₃, 200 MHz): 8.14 (d, J=7.8, 2H), 7.79 (d, J=8.0, 2H), 7.46 (s, 1H), 7.32 (dd, 1H), 6.88 (d, J=8.4, 1H), 4.10-4.0 (m, 4H), 3.96 (s, 3H), 1.89-1.80 (m, 4H), 1.56-1.28 (m, 20H), 0.91 (t, 6H). ¹³C (CDCl₃, 50.3 MHz)—194.33, 166.00, 153.33, 148.59, 142.01, 132.33, 129.14, 129.09, 129.03, 125.36, 113.85, 111.13, 69.21, 69.04, 52.42, 31.91, 29.47, 29.44, 29.37, 29.24, 29.14, 26.12, 26.09, 22.81, 14.27.

Anal. Calcd. for C₃₁H₄₄O₅: C, 74.96; H, 8.93. Found: C, 75.03; H, 8.92.

### (2) Synthesis of Methyl 4-[1-(2-Tosylhydrazono)-1-(3,4-dioctyloxyphenyl)methylbenzoate

In a 50-ml eggplant flask were placed 1.00 g (2.01 mmol) of methyl 4-(3,4-dioctyloxybenzoyl)benzoate and 937 mg (5.03 mmol) of p-tolylsulfonylhydrazide, and 15 ml of MeOH was further added. The mixture was heated under reflux for 5 hours, followed by stirring at room temperature for 24 hours. The solvent was distilled off on a rotary evaporator, and the resulting crude product was purified by silica gel column chromatography (hexane/AcOEt=75/25) and thereby yielded 800 mg of the target compound in a yield of 63%.

¹H NMR (CDCl₃, 200 MHz): 8.17 (d, J=8.2, 2H), 7.85 (d, J=8.2, 2H), 7.32-7.17 (m, 5H), 6.65-6.61 (m, 2H), 3.98-3.90 (m, 4H, s, 3H), 2.43 (s, 3H), 1.85-1.58 (m, 4H), 1.57-1.29 (m, 20H), 0.90 (t, , 6H).

¹³C (CDCl₃, 50.3 MHz) 165.63, 153.10, 150.78, 148.44, 143.79, 135.69, 135.05, 131.17, 130.37, 129.28, 129.02, 128.36, 128.29, 127.7, 125.94, 121.51, 111.85, 111.37, 69.05, 68.91, 52.46, 31.89, 31.85, 29.48, 29.38, 29.31, 29.27, 29.15, 29.16, 26.05, 22.78, 22.75, 21.73, 14.23.

### (3) Synthesis of Methyl 4-[1-(3,4-Dioctyloxyphenyl)-C61]benzoate

In a 50-ml eggplant flask was placed 613 mg (0.920 mmol) of methyl 4-[1-(2-tosylhydrazono)-1-(3,4-dioctyloxyphenyl)methyl]benzoate. After purging the flask with nitrogen, 5.0 ml of pyridine was added, the mixture was stirred at room temperature for 10 minutes, combined with 50.0 mg (0.920 mmol) of sodium methoxide, and stirred for further 30 minutes. A solution of 399 mg (0.550 mmol) of C₆₀ in 10.0 ml of o-dichlorobenzene was slowly added, followed by stirring at 80° C. for 24 hours. The reaction mixture was directly purified by silica gel column chromatography (hexane/AcOEt=95:5). The resulting solid was dissolved in toluene, subjected to isomerization by refluxing for 24 hours, and thereby yielded 112 mg of the target compound in a yield of 17%.

¹H NMR (CDCl₃, 200 MHz): 8.15 (br s, 4H), 7.61 (m, 2H), 6.96 (d, J=8.0, 2H), 4.12-3.98 (m, 4H), 3.92 (s, 3H), 1.83-1.79 (m, 4H), 1.56-1.28 (m, 20H), 0.87 (br s, 6H). ¹³C (CDCl₃, 50.3 MHz): 166.23, 149.18, 148.30, 147.60, 147.54, 144.99, 144.82, 144.42, 144.36, 144.33, 143.97, 143.50, 142.62, 142.57, 141.94, 141.88, 141.80, 140.58, 138.12, 137.67, 130.60, 130.04, 129.85, 129.51, 123.95, 117.10, 113.05, 78.78, 69.81, 68.98, 57.46, 52.31, 32.00, 31.96, 29.65, 29.54, 29.44, 26.26, 26.22, 22.86, 14.38. IR (KBr): 2923, 2853, 1725, 1608, 1511, 1464, 1430, 1275, 1186, 1136, 1107 cm⁻¹. MALDI-TOF MS: m/z 1200.

Anal. Calcd. for C₉₁H₄₄O₄: C, 90.98; H, 3.69 Found: C, 89.41; H, 3.45. UV (CH₂Cl₂) (conc 1.6×10⁻⁶ M) 327 nm (ε₃₂₇=2.52×10⁵, 259 nm (259=6.52×10⁵).

### Example 12

### Solar Battery Cell Including Methyl 4-[1-(3,4-Dioctyloxyphenyl)-C61]benzoate and P3HT

A solar battery cell was prepared by dissolving 15 mg of P3HT and 15 mg of methyl 4-[1-(3,4-dioctyloxyphenyl)-C61]benzoate in 1.0 ml of o-dichlorobenzene to give a solution; applying the solution via spin coating at a number of revolutions of 2000 rpm to give a film; and heating the coated film at 150° C. for 30 minutes. The properties of the cell were measured and found to be as follows:

E_{ff}=1.47%, FF=0.53, V_{oc}=0.56 V, I_{sc}=4.93 mA/cm²

Independently, another cell was prepared by applying the above-prepared solution via spin coating at a number of revolutions of 2000 rpm to give a film; heating the coated film at 150° C. for 30 minutes; forming electrodes by vapor deposition; and carrying out heat treatment at 140° C. for 10 minutes. The properties of the cell were measured and found to be as follows:

E_{ff}=2.12%, FF=0.63, V_{oc}=0.65 V, I_{sc}=5.18 mA/cm²

### Example 13

### Synthesis of 1-(Benzo[b]thiophen-2-yl)-1-[4-(2,3,4,5,6-pentafluorophenoxy)butyl]C61

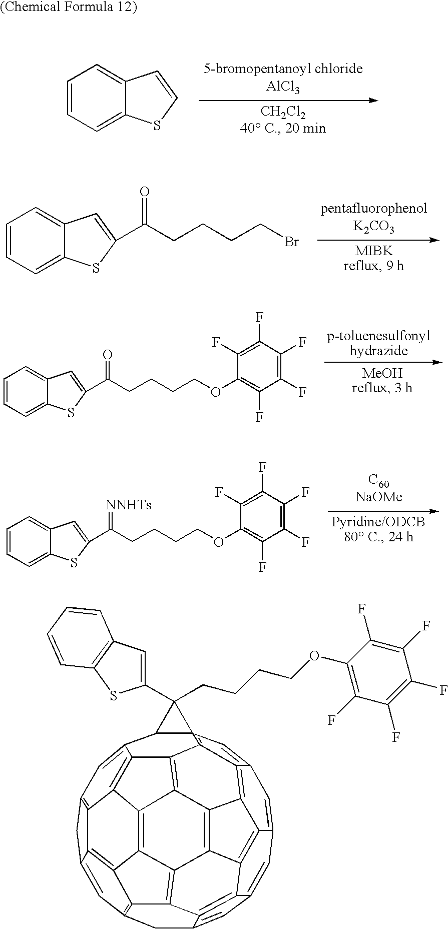

(1) Synthesis of 1-(Benzo[b]thiophen-2-yl)-5-bromopentan-1-one

In a 50-ml eggplant flask was placed 669 mg (3.35 mmol) of 5-bromopentanoyl chloride, and 7.0 ml of dichloromethane was added to give a solution. To the ice-cooled mixture, 497 mg (3.72 mmol) of aluminum trichloride was added, and a solution of 500 mg (3.72 mmol) of benzo[b]thiophene in 3.0 ml of dichloromethane was slowly added. The mixture was stirred under ice-cooling for 30 minutes, followed by stirring at 40° C. for further 30 minutes. After allowing the reaction mixture to cool to room temperature, the solvent was distilled off on a rotary evaporator. The resulting crude product was purified by silica gel column chromatography (hexane/AcOEt=80/20) and thereby yielded 616 mg of the target compound in a yield of 83%.

¹H-NMR (CDCl₃, 200 MHz): 8.77 (d, J=8, 1H), 8.27 (s, 1H), 7.95-7.83 (dd, 1H), 7.52-7.36 (m, 2H), 3.5-3.43 (m, 2H), 3.09-3.00 (m, 2H), 2.02-1.92 (m, 4H). Anal. Calcd. for C₁₃H₁₃BrOS: C, 52.53; H, 4.41. Found: C, 52.42; H, 4.48.

### (2) Synthesis of 1-(Benzo[b]thiophen-2-yl)-5-(2,3,4,5,6-pentafluorophenoxy)pentan-1-one

In a 50-ml eggplant flask were placed 497 mg (1.67 mmol) of 1-(benzo[b]thiophen-2-yl)-5-bromopentan-1-one, 280 mg (1.52 mmol) of perfluorophenol, and 631 mg (4.56 mmol) of potassium carbonate. After purging the flask with nitrogen, 10.0 ml of methyl iso-butyl ketone was added, followed by heating under reflux for 5 hours. The reaction mixture was allowed to cool to room temperature, filtrated through Celite to remove insoluble matter, and the filtrate was diluted with methylene chloride and washed with water. The organic phase was dried over sodium sulfate, from which sodium sulfate was removed by filtration, and the solvent was distilled off on a rotary evaporator. The resulting crude product was purified by silica gel chromatography (hexane/AcOEt=85/15) and thereby yielded 495 mg of the target compound in a yield of 81%.

¹H NMR (CDCl₃, 200 MHz): 8.77 (d, J=8.2, 1H), 8.29 (s, 1H), 7.87-7.83 (dd, 1H), 7.49-7.40 (m, 2H), 4.24-4.18 (m, 2H), 3.13-3.06 (m, 2H), 2.02-1.55 (m, 4H). ¹⁹F(CDCl₃, 188 MHz): −155.94 (d, 2F), −162.31-162.70 (m, 3F). Anal. Calcd. For C₁₉H₁₃F₅O₂S: C, 57.00; H, 3.27. Found: C, 57.06; H, 3.03.

### (3) Synthesis of 1-(Benzo[b]thiophen-2-yl)-5-(2,3,4,5,6-pentafluorophenoxy)pentan-1-one Tosylhydrazone

In a 30-ml eggplant flask were placed 447 mg (1.11 mmol) of 1-(benzo[b]thiophen-2-yl)-5-(2,3,4,5,6-pentafluorophenoxy)pentan-1-one and 624 mg (3.35 mmol) of p-tolylsulfonylhydrazide, and 10 ml of MeOH was added to give a solution. The solution was heated under reflux for 12 hours, followed by stirring at room temperature for 12 hours. The solvent was distilled off on a rotary evaporator, and the resulting crude product was purified by silica gel column chromatography (hexane/AcOEt=65/35) and thereby yielded 316 mg of the target compound in a yield of 50%.

¹H NMR (CDCl₃, 200 MHz): 8.04 (d, J=7.8, 2H) 7.82-7.59 (m, 3H) 7.40-7.25 (m, 4H), 4.13 (m, 2H), 2.76-2.72 (m, 2H), 2.40 (s, 3H), 2.04 (m, 4H). ¹⁹F(CDCl₃, 188 MHz): −155.82 (d, 2F), −161.93-162.03 (m, 3F). Anal. Calcd. for C₂₆H₂₁F₅N₂O₃S₂: C, 54.92; H, 3.72; N, 4.93. Found: C, 54.96; H, 3.72; N, 4.79.

### (4) Synthesis of 1-(Benzo[b]thiophen-2-yl)-1-[4-(2,3,4,5,6-pentafluorophenoxy)butyl]C61

In a 20-ml eggplant flask was placed 173 mg (0.304 mmol) of 1-(benzo[b]thiophen-2-yl)-5-(2,3,4,5,6-pentafluorophenoxy)pentan-1-one tosylhydrazone. After purging the flask with nitrogen, 3.0 ml of pyridine was added, the mixture was stirred at room temperature for 10 minutes, combined with 16.4 mg (0.304 mmol) of sodium methoxide, and stirred for further 30 minutes. A solution of 110 mg (0.152 mmol) of C₆₀ in 5.0 ml of o-dichlorobenzene was slowly added, followed by stirring at 80° C. for 24 hours. The reaction mixture was directly purified by silica gel column chromatography (hexane/AcOEt=85:15). The resulting solid was dissolved in toluene, subjected to isomerization by refluxing for 24 hours, and thereby yielded 167 mg of the target compound in a yield of 60%.

¹H NMR (CDCl₃, 200 MHz): 7.87 (br, s, 2H), 7.37 (br, s, 3H), 4.13-3.80 (m, 2H), 3.09-3.00 (m, 2H), 2.04-1.94 (m, 4H). ¹⁹F(CDCl₃, 188 MHz): −155.79 (d, 2F), −162.38-163.38 (m, 3F).

MALDI-TOF MS: m/z 1102.

### Example 14

### Solar Battery Cell Including 1-(Benzo[b]thiophen-2-yl)-1-[4-(2,3,4,5,6-pentafluorophenoxy)butyl]C61 and P3HT

A solar battery cell was prepared by dissolving 15 mg of P3HT and 15 mg of 1-(benzo[b]thiophen-2-yl)-1-[4-(2,3,4,5,6-pentafluorophenoxy)butyl]C61 in 1.0 ml of o-dichlorobenzene to give a solution; applying the solution via spin coating at a number of revolutions of 2000 rpm to give a film; and heating the coated film at 150° C. for 24 hours.

E_{ff}=0.025%, FF=0.31, V_{oc}=0.33 V, I_{sc}=0.25 mA/cm²

### Example 15

### Synthesis of Methyl 1-(3,4,5-Trioctyloxyphenyl)-C61-4-benzoate

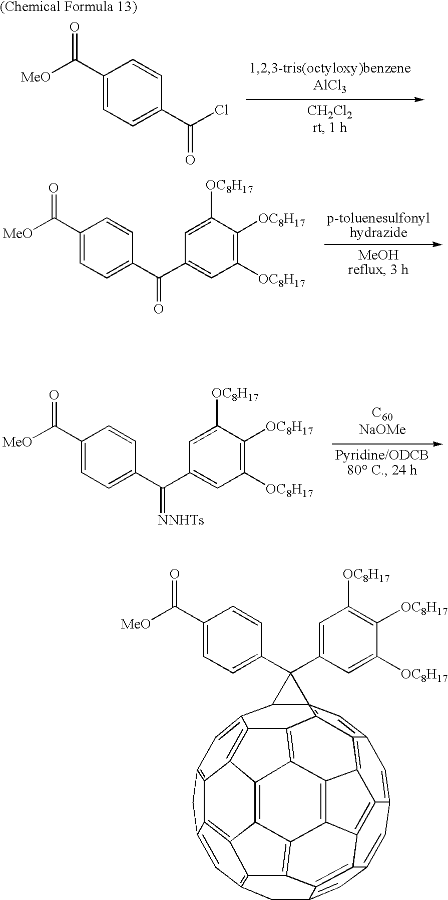

### (1) Synthesis of Methyl 4-(3,4,5-Trioctyloxybenzoyl)benzoate

In a 100-ml eggplant flask was placed 1.54 g (7.76 mmol) of terephthalic acid monomethyl ester chloride. After purging the flask with nitrogen, 10 ml of CH₂Cl₂ was added, followed by ice-cooling. Next, 1.15 g (20.92 mmol) of aluminium trichloride was added, and a solution of 3.99 g (8.62 mmol) of 1,2,3-trioctyloxybenzene in 5 ml of CH₂Cl₂ was slowly added. After stirring for 45 minutes, the solution became transparent, followed by stirring at 40° C. for further 20 minutes. The resulting reddish brown solution was allowed to cool to room temperature, from which the solvent was distilled off on a rotary evaporator. The resulting crude product was purified by silica gel column chromatography (hexane/AcOEt=95/5) and thereby yielded 2.4 g of the target compound in a yield of 50%.

¹H NMR (CDCl₃, 200 MHz): 8.15 (d, J=8.4, 2H), 7.69 (d, J=8.4, 2H), 7.22 (d, J=8.8, 1H), 6.44 (d, J=9.2, 1H), 4.08-4.0 (m, 6H), 3.96 (s, 3H), 1.87-1.73 (m, 6H), 1.57-1.28 (m, 30H), 0.91 (t, J=6.2, 9H).

¹³C (CDCl₃, 50.3 MHz)—198.98, 165.77, 158.52, 157.86, 141.77, 135.77, 132.15, 129.42, 129.15, 128.43, 113.85, 103.63, 68.88, 52.82, 31.96, 31.88, 30.32, 29.59, 29.43, 29.39, 29.34, 29.21, 26.10, 22.79, 14.23.

FT-IR (KBr): 2919, 2873, 2850, 1727, 1683, 1625, 1586, 1499, 1468, 1438, 1350, 1282, 1206, 1105.

Anal. Cal. C₃₉H₆₀O₆. C, 74.96; H, 9.68 Found: C, 74.85; H, 9.37.

MS (EI) m/z 624

### (2) Synthesis of 1-(4-Methoxycarbonylphenyl)-1-(3,4,5-trioctyloxyphenyl)methanone p-Tolylsulfonylhydrazone

In a 100 ml eggplant flask were placed 2.29 g (3.66 mmol) of methyl 4-(3,4,5-trioctyloxybenzoyl)benzoate and 2.04 g (10.99 mmol) of p-toluenesulfonylhydrazide, followed by refluxing for 4 hours. The reaction mixture was allowed to cool to room temperature, from which the solvent was distilled off on a rotary evaporator. The resulting crude product was purified by silica gel column chromatography (hexane/AcOEt=80/20) and thereby yielded 1.8 g of the target compound in a yield of 63%.

¹H NMR (CDCl₃, 200 MHz) 8.20 (d, J=8.4, 2H), 7.81 (d, J=8.4, 2H), 7.35 (d, J=8.4, 2H), 7.18 (d, J=8.2, 2H), 6.2 (s, 2H), 4.05-3.88 (m, 6H, s, 3H), 2.43 (s, 3H), 1.84-1.74 (m, 6H), 1.59-1.297 (m, 30H), 0.90 (t, 9H).

FT-IR (KBr): 3202, 2925, 2855, 1722, 1707, 1618, 1514, 1411, 1292, 1168, 1104, 1077.

Anal. Cal. C₄₆H₆₈N₂O₇S. C, 69.66; H, 8.64; N, 3.53. Found: C, 69.55; H, 8.23; N, 3.64.

MS (EI) m/z 792

### (3) Synthesis of Methyl 1-(3,4,5-Trioctyloxyphenyl)-C61-4-benzoate

In a 200-ml eggplant flask was placed 737 mg (0.929 mmol) of 1-(4-methoxycarbonylphenyl)-1-(3,4,5-trioctyloxyphenyl)methanone p-tolylsulfonylhydrazone. After purging the flask with nitrogen, 15 ml of pyridine was added, the mixture was stirred at room temperature for 10 minutes, combined with 50.2 mg (0.929 mmol) of sodium methoxide, and stirred at room temperature for further 20 minutes. A solution of 401.8 mg (0.557 mmol) of C₆₀ in 35 ml of ODCB was slowly added, followed by stirring at 80° C. for 24 hours. The reaction mixture was directly purified by silica gel column chromatography (initially hexane, then hexane/AcOEt=75/25). The resulting solid was dissolved in toluene, subjected to isomerization by refluxing for 24 hours, and thereby yielded 163 mg of the target compound in a yield of 22%.

¹H NMR (CDCl₃, 200 MHz): 8.32 (d, J=8.4, 2H), 8.13 (d, J=8.4, 2H), 7.63 (d, J=8.6, 1H), 6.56 (d, J=5.6, 1H), 4.21-3.95 (m, 6H), 3.91 (s, 3H), 1.85-1.59 (m, 6H), 1.45-1.27 (m, 30H), 0.87 (t, J=6.6, 9H).

¹³C (CDCl₃, 50.3 MHz)-166.42, 151.52, 149.54, 148.18, 148.03, 147.72, 145.49, 145.19, 144.96, 144.85, 144.36, 144.27, 143.94, 143.81, 143.60, 143.49, 143.15, 142.62, 142.19, 142.09, 141.88, 141.67, 140.62, 140.35, 138.25, 137.80, 137.60, 136.36, 134.62, 131.18, 129.63, 129.48, 129.30, 126.42, 126.24, 115.82, 109.41, 104.75, 101.28, 78.65, 73.50 (bridgehead), 72.97, 70.39, 68.61, 52.73 (bridge), 52.23, 31.96, 30.36, 30.17, 29.43, 26.38, 26.19, 26.02, 22.85, 14.32

FT-IR (KBr): 2922, 2851, 1725, 1609, 1505, 1455, 1431, 1274, 1187, 1098, 1020.

Anal. Cal. C₉₉H₆₀O₅. C, 89.43; H, 4.55 Found: C, 89.08; H, 3.94.

### Example 16

### Solar Battery Cell Including Methyl 1-(3,4,5-Trioctyloxyphenyl)-C61-4-benzoate and P3HT

A solar battery cell was prepared by dissolving 15 mg of P3HT and 15 mg of methyl 1-(3,4,5-trioctyloxyphenyl)-C61-4-benzoate in 1.0 ml of o-dichlorobenzene to give a solution; applying the solution via spin coating at a number of revolutions of 2000 rpm to give a film; and heating the coated film at 100° C. for 30 minutes. The properties of the cell were measured and found to be as follows:

E_{ff}=1.50%, FF=0.49, V_{oc}=0.66 V, I_{sc}=4.60 mA/cm²

### Example 17

### Synthesis of Methyl 1-(3,4,5-trioctyloxyphenyl)-C71-4-benzoate

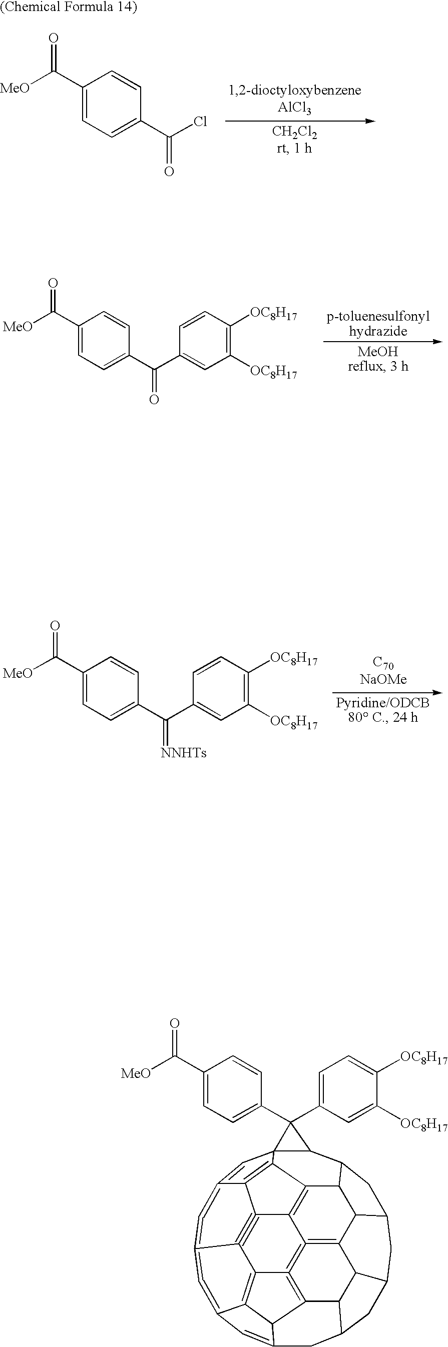

In a 50-ml eggplant flask was placed 650 mg (0.977 mmol) of methyl 4-{1-(2-tosylhydrazono)-1-(3,4-dioctyloxyphenyl)methyl}benzoate. After purging the flask with nitrogen, 15 ml of pyridine was added, the mixture was stirred at room temperature for 10 minutes, combined with 52.8 mg (0.977 mmol) of sodium methoxide, and stirred for further 30 minutes. A solution of 492.7 mg (0.586 mmol) of C₇₀ in 15 ml of ODCB was slowly added, followed by stirring at 80° C. for 24 hours. The reaction mixture was directly purified by silica gel column chromatography (initially hexane, then hexane/AcOEt=75/25). The resulting solid was dissolved in toluene, subjected to isomerization by refluxing for 24 hours, and thereby yielded 245 mg of the target compound in a yield of 32%.

¹H NMR (CDCl₃, 200 MHz): 8.16 (m, 4H), 7.6 (d, 1H), 7.35 (br, s, 1H), 6.92 (d, 1H), 4.13-3.94 (m, 4H), 3.89 (s, 3H), 1.80-1.78 (m, 4H), 1.60-1.27 (m, 20H), 0.87 (t, 6H).

¹³C (CDCl₃, 50.3 MHz)—166.10, 155.19, 155.01, 151.61, 151.06, 150.80, 150.51, 150.14, 149.33, 149.08, 148.79, 148.34, 148.14, 147.92, 147.61, 147.13, 146.60, 145.98, 145.61, 145.39, 144.76, 144.27, 144.14, 143.59, 143.42, 143.01, 142.29, 141.47, 141.21, 139.87, 139.59, 138.07, 133.67, 132.51, 130.93, 130.51, 130.28, 130.14, 129.45, 128.67, 128.34, 123.44, 116.50, 113.13, 71.48, 69.82 (bridgehead), 69.58, 68.97, 52.30, 41.32 (bridge), 32.01, 31.72, 29.70, 29.43, 26.27, 22.86, 14.34.

MALDI-TOF MS: m/z 1320 [M]⁻²

FT-IR (KBr): 2919, 2850, 1725, 1697, 1509, 1454, 1428, 1272, 1176, 1133, 1106.

### Example 18

### Solar Battery Cell Including Methyl 1-(3,4,5-trioctyloxyphenyl)-C71-4-benzoate and P3HT

A solar battery cell was prepared by dissolving 15 mg of P3HT and 15 mg of methyl 1-(3,4,5-trioctyloxyphenyl)-C71-4-benzoate in 1.0 ml of o-dichlorobenzene to give a solution; applying the solution via spin coating at a number of revolutions of 2000 rpm to give a film; and heating the coated film at 100° C. for 30 minutes. The properties of the cell were measured and found to be as follows:

E_{ff}=1.60%, FF=0.55, V_{oc}=0.60 V, I_{sc}=4.90 mA/cm²

### Example 19

### Solar Battery Cell Including Methyl 1-(3,4,5-trioctyloxyphenyl)-C71-4-benzoate and MEH-PPV

A solution was prepared by dissolving 2 mg of MEH-PPV and 8 mg of methyl 1-(3,4,5-trioctyloxyphenyl)-C71-4-benzoate in 0.5 mL of o-DCB, and a solar battery was prototyped using the solution by applying the solution via spin coating at a number of revolutions of 2000 rpm to form a film; and heating the coated film at 100° C. for 10 minutes.

E_{ff}=0.76%, FF=0.32, V_{oc}=0.82 V, I_{sc}=2.84 mA/cm²

### Example 20

### Synthesis of 1-(3,4-Dioctyloxyphenyl)-1-(4-nitrophenyl)-C61

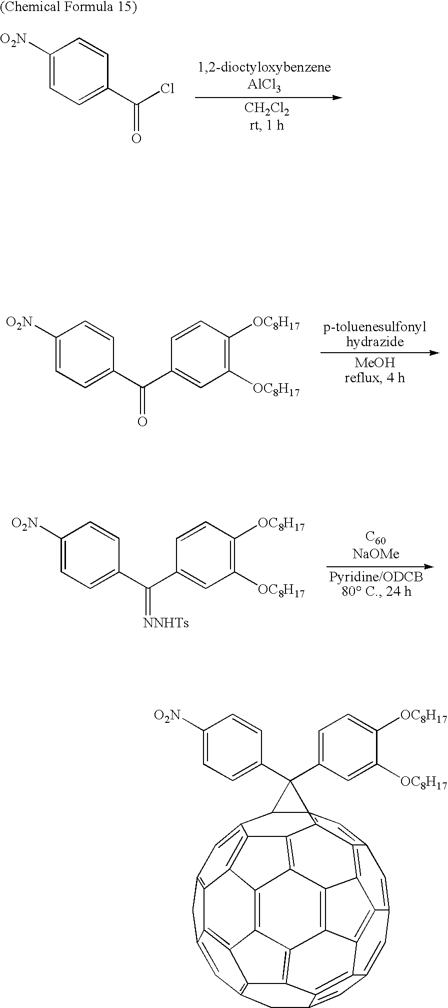

### (1) Synthesis of (4-Nitrophenyl)-(3,4-dioctyloxyphenyl)methanone

In a 100 ml eggplant flask was placed 4.99 g (26.9 mmol) of 4-nitrobenzoyl chloride. After purging the flask with nitrogen, 20 ml of CH₂Cl₂ was added, followed by ice-cooling. Next, 3.98 g (29.9 mmol) of aluminium trichloride was added, and a solution of 10.0 g (29.89 mmol) of 1,2-dioctyloxybenzene in 5 ml of CH₂Cl₂ was slowly added. After stirring for 45 minutes, the solution became transparent, followed by stirring at 40° C. for further 20 minutes. The resulting reddish brown solution was allowed to cool to room temperature, from which the solvent was distilled off on a rotary evaporator. The resulting crude product was purified by silica gel column chromatography (hexane/AcOEt=85/15) and thereby yielded 11.3 g of the target compound in a yield of 87%.

¹H NMR (CDCl₃, 200 MHz): 8.33 (d, J=10, 2H), 7.89 (d, J=6.6, 2H), 7.46 (s, 1H), 7.28 (dd, 1H), 6.88 (d, J=8.4, 1H), 4.10-4.0 (m, 4H), 1.90-1.81 (m, 4H), 1.55-1.28 (m, 20H), 0.91 (t, 6H).

¹³C (CDCl₃, 50.3 MHz)-192.99, 153.75, 149.04, 148.78, 143.66, 130.00, 128.38, 125.49, 123.11, 113.53, 111.08, 69.22, 69.06, 31.90, 29.46, 29.43, 29.37, 29.22, 29.10, 26.12, 26.08, 22.80, 14.26.

FT-IR (KBr): 2926, 2853, 1654, 1588, 1524, 1466, 1418, 1388, 1346, 1305, 1282, 1224, 1122.

Anal. Cal. C₂₉H₄₁NO₅. C, 72.02; H, 8.54; N, 2.90. Found: C, 71.92; H, 8.27; N, 2.82.

MS (EI) m/z 483

### (2) Synthesis of (4-Nitrophenyl)-(3,4-dioctyloxyphenyl)methanone p-Tolylsulfonylhydrazone

In a 100 ml eggplant flask were placed 3 g (6.2 mmol) of (4-nitrophenyl)-(3,4-dioctyloxyphenyl)methanone and 3.4 g (18.6 mmol) of p-tolylsulfonylhydrazide, followed by refluxing for 4 hours. The reaction mixture was allowed to cool to room temperature, from which the solvent was distilled off on a rotary evaporator, and the resulting crude product was purified by silica gel column chromatography (hexane to hexane/AcOEt=85/15) and thereby yielded 2.78 g of the target compound in a yield of 69%.

¹H NMR (CDCl₃, 200 MHz): 8.12 (m, 3H), 7.86 (d, J=8.2, 2H), 7.64 (m, 2H), 7.36 (d, J=8.4, 1H), 7.00 (d, J=8.2, 1H), 6.68 (d, J=9.8, 1H), 6.57 (d, J=2, 1H), 4.07 (m, 4H), 2.43 (s, 3H), 1.89-1.73 (m, 4H), 1.49-1.20 (m, 20H), 0.89 (t, 6H).

¹³C (CDCl₃, 50.3 MHz)—151.26, 150.43, 149.79, 147.76, 143.98, 142.31, 135.03, 129.40, 127.94, 127.53, 123.02, 121.23, 120.73, 113.70, 112.58, 69.27, 69.03, 31.84, 31.81, 31.58, 29.37, 29.31, 29.27, 29.18, 26.08, 26.02, 22.71, 21.66, 14.18.

Anal. Cal. C₃₆H₄₉N₃O₆S. C, 66.33; H, 7.58; N, 6.45. Found: C, 67.03; H, 7.53; N, 6.30.

FT-IR (KBr): 2925, 2856, 1598, 1517, 1423, 1348, 1254, 1170.

MS (EI) m/z 651

### (3) Synthesis of 1-(3,4-Dioctyloxyphenyl)-1-(4-nitrophenyl)-C61

In a 100-ml eggplant flask was placed 1.48 g (2.28 mmol) of (4-nitrophenyl)-(3,4-dioctyloxyphenyl)methanone p-tolylsulfonylhydrazone. After purging the flask with nitrogen, 7.0 ml of pyridine was added, the mixture was stirred at room temperature for 10 minutes, combined with 123 mg (2.28 mmol) of sodium methoxide, and stirred at room temperature for 20 minutes. A solution of 986 mg (1.36 mmol) of C₆₀ in 15 ml of ODCB was slowly added, followed by stirring at 80° C. for 24 hours. The reaction mixture was directly purified by silica gel column chromatography (initially hexane, then hexane/AcOEt=75/25). The resulting solid was dissolved in toluene, subjected to isomerization by refluxing for 24 hours, and thereby yielded 821 mg of the target compound in a yield of 26%.

¹H NMR (CDCl₃, 200 MHz): 8.36 (m, 2H), 8.13 (d, J=8.6, 1H) 7.62 (m, 2H), 7.32 (d, J=8.6, 1H), 6.98 (d, J=8.2, 1H), 4.12-3.89 (m, 4H), 1.86-1.74 (m, 4H), 1.56-1.25 (m, 20H), 0.95 (t, 6H).

¹³C (CDCl₃, 50.3 MHz)—149.53, 149.09, 149.00, 148.53, 147.82, 147.13, 146.96, 146.08, 144.90, 144.68, 144.50, 144.42, 144.32, 144.12, 143.54, 142.73, 142.61, 141.93, 141.82, 140.70, 138.24, 137.62, 131.49, 131.43, 130.64, 129.27, 128.57, 124.05, 123.94, 123.49, 121.11, 117.13, 114.78, 114.00, 113.23, 78.41, 69.93, 69.40, 69.05, 68.16, 56.60, 41.38, 38.86, 31.96, 30.52, 29.85, 29.65, 29.54, 29.43, 29.08, 26.22, 23.94, 23.17, 22.85, 14.32.

FT-IR (KBr): 2924, 2854, 1654, 1596, 1514, 1466, 1345, 1267

Anal. Cal: C₈₉H₄₁NO₄, C, 89.96; H, 3.48; N, 1.18. Found: C, 89.13; H, 3.43; N, 1.16.

### Example 21

### Solar Battery Cell Including 1-(3,4-Dioctyloxyphenyl)-1-(4-nitrophenyl)-C61 and P3HT

A solar battery cell was prepared by dissolving 15 mg of P3HT and 15 mg of 1-(3,4-Dioctyloxyphenyl)-1-(4-nitrophenyl)-C61 in 1.0 ml of o-dichlorobenzene to give a solution; applying the solution via spin coating at a number of revolutions of 2000 rpm to give a film; and heating the coated film at 100° C. for 30 minutes. The properties of the cell were measured and found to be as follows:

E_{ff}=0.16%, FF=0.37, V_{oc}=0.19 V, I_{sc}=2.28 mA/cm²

### Example 22

### Synthesis of 1-(4-cyanophenyl)-1-(3,4-dioctyloxyphenyl)-C61

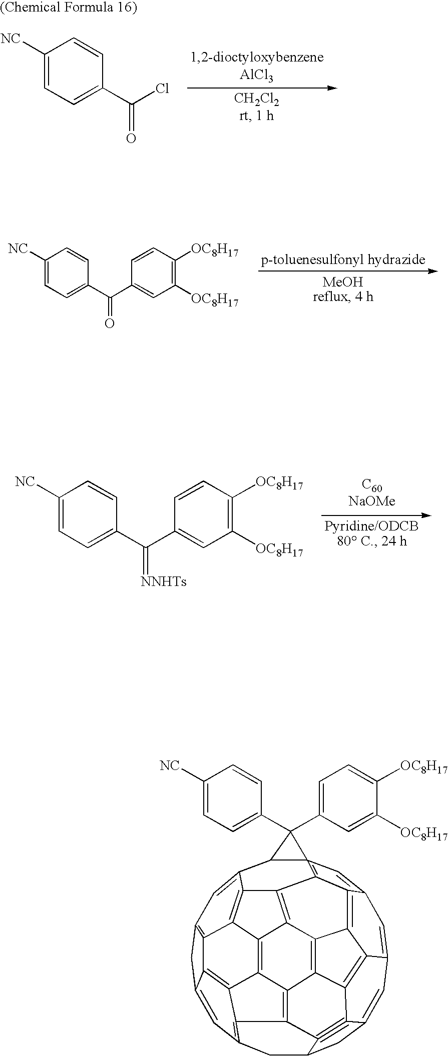

### (1) Synthesis of (4-Cyanophenyl)-(3,4-dioctyloxyphenyl)methanone

In a 100-ml eggplant flask was placed 3.12 g (18.83 mmol) of 4-cyanobenzoyl chloride. After purging the flask with nitrogen, 20 ml of CH₂Cl₂ was added, followed by ice-cooling. Next, 2.79 g (20.92 mmol) of aluminium trichloride was added, and a solution of 7.0 g (20.92 mmol) of 1,2-dioctyloxybenzene in 5 ml of CH₂Cl₂ was slowly added. After stirring for 45 minutes, the solution became transparent, followed by stirring at 40° C. for further 20 minutes. The resulting reddish brown solution was allowed to cool to room temperature, from which the solvent was distilled off on a rotary evaporator. The resulting crude product was purified by silica gel column chromatography (hexane/AcOEt=85/15) and thereby yielded 6.77 g of the target compound in a yield of 78%.

¹H NMR (CDCl₃, 200 MHz): 7.83 (m, 4H), 7.44 (s, 1H), 7.27 (dd, 1H), 6.87 (d, J=8.4, 1H), 4.10-4.0 (m, 4H), 1.90-1.80 (m, 4H), 1.58-1.28 (m, 20H), 0.91 (t, 6H).

¹³C (CDCl₃, 50.3 MHz)-193.24, 153.63, 148.74, 141.95, 131.71, 129.60, 128.41, 125.41, 117.89, 114.76, 113.60, 111.07, 69.21, 69.05, 31.89, 29.44, 29.41, 29.35, 29.21, 29.09, 26.10, 26.07, 22.79, 14.26.

FT-IR (KBr): 2952, 2924, 2869, 2852, 2229, 1652, 1590, 1577, 1521, 1466, 1436, 1420, 1392, 1348, 1310, 1301, 1282, 1224, 1178, 1149.

Anal. Cal. C₃₀H₄₁NO₃. C, 77.71; H, 8.91; N, 3.02. Found: C, 77.67; H, 9.24; N, 2.95.

### (2) Synthesis of (4-Cyanophenyl)-(3,4-dioctyloxyphenyl)methanone p-Tolylsulfonylhydrazone

In a 100 ml eggplant flask were placed 2.87 g (6.12 mmol) of (4-cyanophenyl)-(3,4-dioctyloxyphenyl)methanone and 3.4 g (18.5 mmol) of p-toluenesulfonylhydrazide, followed by refluxing for 4 hours. The reaction mixture was allowed to cool to room temperature, from which the solvent was distilled off on a rotary evaporator. The resulting crude product was purified by silica gel column chromatography (hexane/AcOEt=80/20) and thereby yielded 2.76 g of the target compound in a yield of 71%.

¹H NMR (CDCl₃, 200 MHz) 8.10 (s, 1H), 7.85 (d, J=8.2, 2H), 7.54 (m, 4H) 7.34 (d, J=8.0, 2H), 6.98 (d, J=8.2, 1H), 6.66 (d, J=8.2, 1H), 6.56 (d, J=2.0, 1H), 4.04-3.85 (m, 4H), 2.41 (s, 3H), 1.83-1.74 (m, 4H), 1.48-1.29 (m, 20H), 0.88 (t, J=3, 6H).

¹³C (CDCl₃, 50.3 MHz)—151.50, 150.14, 149.49, 143.61, 140.43, 134.94, 131.35, 129.17, 127.50, 127.31, 121.19, 120.64, 117.93, 113.52, 112.50, 112.27, 69.00, 68.75, 31.63, 31.61, 29.18, 29.12, 29.08, 29.00, 25.89, 25.84, 22.52, 21.43, 13.99.

FT-IR (KBr): 3151, 2923, 2855, 1599, 1514, 1472, 1405, 1346, 1305.

Anal. Cal: C₃₇H₄₉N₃O₄S, C, 70.33; H, 7.82; N, 6.65. Found: C, 70.07; H, 7.74; N, 6.53.

### (3) Synthesis of 1-(4-Cyanophenyl)-1-(3,4-dioctyloxyphenyl)-C61

In a 100-ml eggplant flask was placed 1.16 g (1.83 mmol) of (4-cyanophenyl)-(3,4-dioctyloxyphenyl)methanone p-tolylsulfonylhydrazone. After purging the flask with nitrogen, 7.0 ml of pyridine was added, the mixture was stirred at room temperature for 10 minutes, combined with 99.0 mg (1.83 mmol) of sodium methoxide, and stirred at room temperature for further 20 minutes. A solution of 794 mg (1.10 mmol) of C₆₀ in 15 ml of ODCB was slowly added, followed by stirring at 80° C. for 24 hours. The reaction mixture was directly purified by silica gel column chromatography (initially hexane, then hexane/AcOEt=75/25). The resulting solid was dissolved in toluene, subjected to isomerization by refluxing for 24 hours, and thereby yielded 661.5 mg of the target compound in a yield of 19%.

¹H NMR (CDCl₃, 200 MHz): 8.23 (d, J=9, 2H), 7.77 (d, J=8.2, 2H), 7.59 (m, 2H), 6.96 (d, J=8.2, 1H), 4.11-3.97 (m, 4H), 1.86-1.73 (m, 4H), 1.46-1.28 (m, 20H), 0.88 (t, J=7.4, 6H).

¹³C (CDCl₃, 50.3 MHz)—149.39, 148.41, 147.18, 147.03, 144.87, 144.84, 144.81, 144.65, 144.42, 144.33, 144.27, 144.12, 144.09, 144.02, 143.97, 143.47, 143.43, 142.64, 142.61, 142.52, 141.88, 141.77, 140.60, 138.15, 137.55, 132.36, 131.21, 129.42, 128.76, 127.95, 125.03, 123.93, 118.27, 117.01, 113.11, 111.76, 78.40, 69.84, 68.97, 56.93, 31.96, 31.92, 29.62, 29.50, 29.42, 26.24, 26.20, 22.85, 22.82, 14.35.

FT-IR (KBr): 2921, 2852, 1508, 1457, 1264, 1249.

Anal. Cal. C₉₀H₄₁NO₂. C, 92.52; H, 3.54; N, 1.20. Found: C, 91.37; H, 3.54; N, 1.11.

### Example 23

### Solar Battery Cell Including 1-(4-Cyanophenyl)-1-(3,4-dioctyloxyphenyl)-C61 and P3HT

A solar battery cell was prepared by dissolving 15 mg of P3HT and 15 mg of 1-(4-cyanophenyl)-1-(3,4-dioctyloxyphenyl)-C61 in 1.0 ml of o-dichlorobenzene to give a solution; applying the solution via spin coating at a number of revolutions of 2000 rpm to give a film; and heating the coated film at 100° C. for 30 minutes. The properties of the cell were measured and found to be as follows:

E_{ff}=0.8⁴%, FF=0.40, V_{oc}=0.52 V, I_{sc}=4.09 mA/cm²

### Example 24

### Synthesis of Dimethyl 1-(3,4-dioctyloxyphenyl)-C61-benzene-1,3-dioate

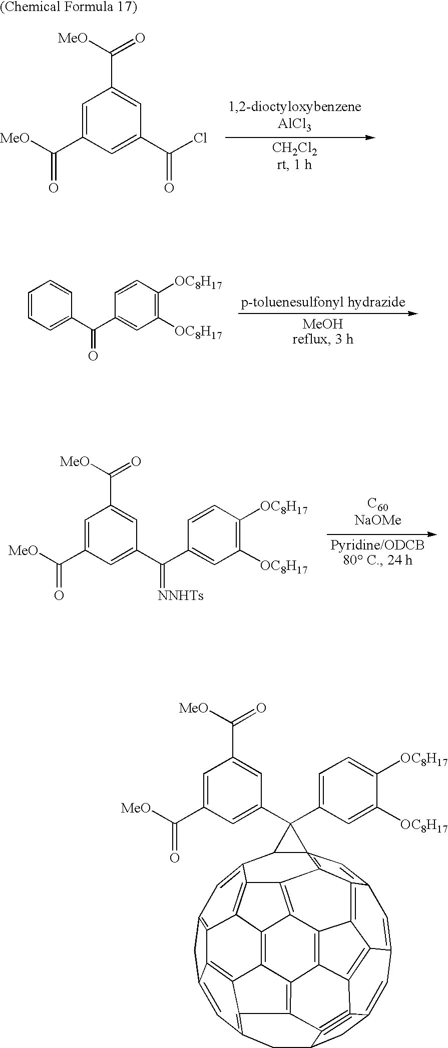

### (1) Synthesis of Dimethyl 5-(3,4-Dioctyloxybenzoyl)benzene-1,3-dioate

In a 100-ml eggplant flask was placed 1.17 g (4.57 mmol) of dimethyl 5-chlorocarbonylbenzene-1,3-dioate. After purging the flask with nitrogen, 10 ml of CH₂Cl₂ was added, followed by ice-cooling. Next, 1.15 g (20.92 mmol) of aluminium trichloride was added, and a solution of 1.70 g (5.08 mmol) of 1,2-dioctyloxybenzene in 5 ml of CH₂Cl₂ was slowly added. After stirring for 45 minutes, the solution became transparent, followed by stirring at 40° C. for further 20 minutes. The resulting reddish brown solution was allowed to cool to room temperature, from which the solvent was distilled off on a rotary evaporator. The resulting crude product was purified by silica gel column chromatography (hexane/AcOEt=85/15) and thereby yielded 2.1 g of the target compound in a yield of 83%.

¹H NMR (CDCl₃, 200 MHz): 8.95-8.93 (m, 1H), 8.90 (d, 1H), 8.52 (m, 1H), 8.56 (d, 1H), 7.46 (d, 1H), 7.29 (d, 1H), 6.89 (d, 1H), 4.10-4.0 (m, 4H), 3.96 (s, 3H), 1.89-1.80 (m, 4H), 1.56-1.28 (m, 20H), 0.91 (t, 6H).

¹³C (CDCl₃, 50.3 MHz)—192.99, 165.11, 164.93, 164.23, 153.50, 148.75, 139.01, 136.16, 135.40, 135.01, 134.70, 134.24, 134.09, 132.98, 131.61, 130.90, 130.56, 128.67, 125.29, 113.78, 111.27, 69.23, 69.05, 52.89, 52.60, 31.89, 29.42, 29.36, 29.21, 29.12, 26.11, 26.09, 22.78, 14.23.

FT-IR (KBr): 2924, 2854, 1732, 1640, 1447, 1430, 1394, 1339, 1254.

Anal. Cal. C₃₃H₄₆O₇, C, 71.45; H, 8.36 Found: C, 71.70; H, 8.24

EI-MS: m/z 554

### (2) Synthesis of 1-(4-Methoxycarbonylphenyl)-1-(3,4-dioctyloxyphenyl)methanone p-Tolylsulfonylhydrazone

In a 100 ml eggplant flask were placed 261 mg (0.470 mmol) of dimethyl 5-(3,4-dioctyloxybenzoyl)benzene-1,3-dioate and 262.9 mg (1.41 mmol) of p-toluenesulfonylhydrazide, followed by refluxing for 4 hours. The reaction mixture was allowed to cool to room temperature, from which the solvent was distilled off on a rotary evaporator. The resulting crude product was purified by silica gel column chromatography (initially hexane, then hexane/AcOEt=75/25) and thereby yielded 253 mg of the target compound in a yield of 75%.

¹H NMR (CDCl₃, 200 MHz): 8.80 (s, 1H), 8.67 (d, 1H), 8.24 (s, 1H), 8.01-7.76 (m, 4H), 7.37-7.20 (d, 2H), 6.98 (d, 1H), 6.7-6.55 (m, 2H), 4.11-3.86 (m, 10H), 2.43 (s, 3H), 1.89-1.72 (m, 4H), 1.30-1.21 (m, 20H), 0.89 (t, 6H).

¹³C (CDCl₃, 50.3 MHz)—165.23, 164.79, 164.67, 150.06, 150.85, 150.37, 149.59, 148.50, 143.84, 143.71, 137.74, 134.99, 134.93, 134.11, 133.36, 132.32, 131.56, 131.06, 130.79, 130.38, 129.32, 129.21, 128.37, 127.67, 121.54, 120.96, 113.62, 112.71, 111.89, 111.40, 69.22, 68.99, 52.51, 52.36, 31.82, 31.79, 29.31, 29.26, 29.19, 26.08, 26.01, 22.69, 21.67, 14.15.

FT-IR (KBr): 3182, 2952, 2925, 2855, 1731, 1598, 1511, 1430, 1343, 1246.

Anal. Cal. C₄₀H₅₄N₂O₈S, C, 66.46; H, 7.53; N, 3.87. Found: C, 66.22; H, 7.21; N, 3.20

EI-MS: m/z 722

### (3) Synthesis of Dimethyl 1-(3,4-Dioctyloxyphenyl)-C61-benzene-1,3-dioate

In a 50-ml eggplant flask was placed 218 mg (0.300 mmol) of 1-(4-methoxycarbonylphenyl)-1-(3,4-dioctyloxyphenyl)methanone p-tolylsulfonylhydrazone. After purging the flask with nitrogen, 3.0 ml of pyridine was added, the mixture was stirred at room temperature for 10 minutes, combined with 16.3 mg (0.300 mmol) of sodium methoxide, and stirred at room temperature for further 20 minutes. A solution of 131 mg (0.180 mmol) of C60 in 10 ml of ODCB was slowly added, followed by stirring at 80° C. for 24 hours. The reaction mixture was directly purified by silica gel column chromatography (hexane/AcOEt=80:20). The resulting solid was dissolved in toluene, subjected to isomerization by refluxing for 24 hours, and thereby yielded 89 mg of the target compound in a yield of 39%.

¹H NMR (CDCl₃, 200 MHz): 8.93 (m, 2H), 8.69 (d, 1H) 7.67 (dd, 1H), 7.56 (d, 1H), 6.96 (d, 1H), 4.13-3.98 (m, 4H), 3.97 (s, 6H), 1.85-1.76 (m, 4H), 1.46-1.28 (m, 20H), 0.89 (t, 6H).

¹³C (CDCl₃, 50.3 MHz)—165.42, 149.27, 148.39, 147.43, 147.14, 145.15, 144.92, 144.88, 144.84, 144.80, 144.46, 144.36, 144.18, 144.10, 144.02, 143.54, 143.47, 142.74, 142.69, 142.65, 142.59, 141.92, 141.84, 140.66, 140.63, 140.37, 138.16, 137.64, 135.55, 130.93, 130.09, 129.87, 123.99, 117.02, 113.20, 78.69, 69.83, 69.02, 56.72, 52.67, 32.00, 31.96, 29.65, 29.54, 29.45, 26.27, 26.22, 22.87, 22.86, 14.36

FT-IR (KBr): 2923, 2853, 1730, 1717, 1508, 1427, 1335, 1240.

Anal. Cal.: C₉₃H₄₆O₆, C, 88.70; H, 3.68. Found: C, 87.97; H, 3.65

### Example 25

### Solar Battery Cell Including Dimethyl 1-(3,4-Dioctyloxyphenyl)-C61-benzene-1,3-dioate and P3HT

A solar battery cell was prepared by dissolving 15 mg of P3HT and 15 mg of dimethyl 1-(3,4-dioctyloxyphenyl)-C61-benzene-1,3-dioate in 1.0 ml of o-dichlorobenzene to give a solution; applying the solution via spin coating at a number of revolutions of 2000 rpm to give a film; and heating the coated film at 100° C. for 30 minutes. The properties of the cell were measured and found to be as follows:

E_{ff}=1.00%, FF=0.59, V_{oc}=0.54 V, I_{sc}=3.13 mA/cm²

### Example 26

### Synthesis of 1-(3-Nitrophenyl)-1-(3,4-dioctyloxyphenyl)-C61

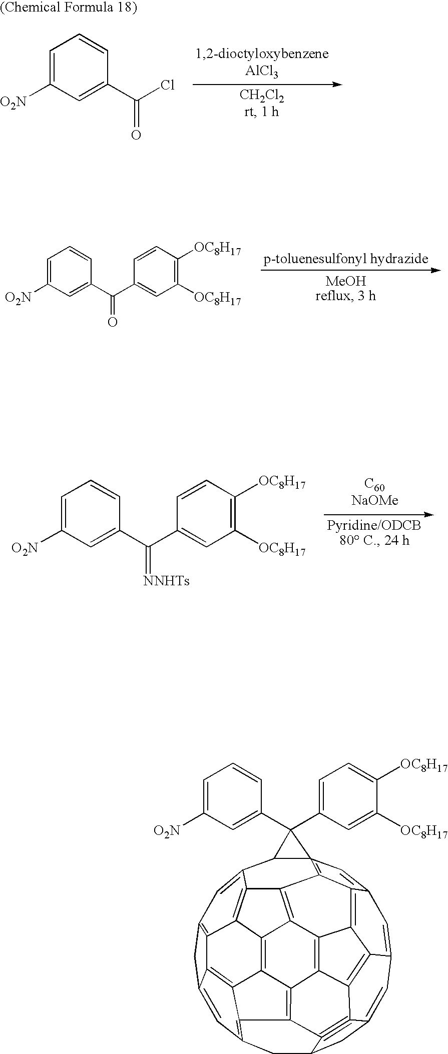

### (1) Synthesis of (3-Nitrophenyl)-(3,4-dioctyloxyphenyl)methanone

In a 200-ml eggplant flask was placed 4.99 g (26.9 mmol) of 3-nitrobenzoyl chloride. After purging the flask with nitrogen, 30 ml of CH₂Cl₂ was added, followed by ice-cooling. Next, 3.98 g (29.9 mmol) of aluminium trichloride was added, and a solution of 10.0 g (29.9 mmol) of 1,2-dioctyloxybenzene in 10 ml of CH₂Cl₂ was slowly added. The mixture was stirred at room temperature for 2 hours and diluted with cold water. After extracting with methylene chloride, the organic phase was washed with water and dried over sodium sulfate. The solvent was distilled off on a rotary evaporator, and the resulting crude product was purified by silica gel column chromatography (hexane/AcOEt=85/15) and thereby yielded 10.5 g of the target compound in a yield of 81%.

¹H NMR (CDCl₃, 200 MHz) 8.56 (s, 1H), 8.42 (d, 1H) 8.09 (d, 1H), 7.71-7.63 (m, 1H), 7.46 (s, 1H), 7.30 (m, 2H), 6.90 (d, 1H), 4.11-4.02 (m, 4H), 1.87-1.81 (m, 4H), 1.58-1.29 (m, 20H), 0.88 (t, 6H).

¹³C (CDCl₃, 50.3 MHz)—192.30, 153.69, 148.83, 147.56, 145.64, 145.49, 139.60, 134.85, 129.13, 128.33, 125.79, 125.29, 124.11, 120.97, 119.76, 114.19, 113.76, 111.40, 111.23, 69.26, 69.07, 68.82, 31.88, 29.43, 29.35, 29.23, 29.12, 26.09, 22.78, 14.23.

FT-IR (KBr): 2954, 2925, 2853, 1645, 1577, 1536, 1515, 1503, 1377, 1347, 1277.

Anal. Cal.: C₂₉H₄₁NO₅, C, 72.02; H, 8.54; N, 2.90. Found, C, 72.04; H, 8.44; N, 2.82.

EI-MS: m/z 483

### (2) Synthesis of 1-(3-Nitrophenyl)-1-(3,4-dioctyloxyphenyl)methanone p-Tolylsulfonylhydrazone

In a 100 ml eggplant flask were placed 2.00 g (4.31 mmol) of 1-(3-nitrophenyl)-1-(3,4-dioctyloxyphenyl)methanone and 2.40 g (12.9 mmol) of p-toluenesulfonylhydrazide, followed by refluxing for 5 hours. The reaction mixture was allowed to cool to room temperature, from which the solvent was distilled off on a rotary evaporator. The resulting crude product was purified by silica gel column chromatography (hexane/AcOEt=70/30) and thereby yielded 2.40 g of the target compound in a yield of 88%.

¹H NMR (CDCl₃, 200 MHz): 8.36 (dd, 1H), 7.95 (t, 1H) 7.84 (d, 1H), 7.75 (m, 2H) 7.56 (d, 1H) 7.34-7.19 (m, 3H), 6.69 (d, 1H), 6.54 (d, 1H), 3.99-3.93 (m, 4H), 2.44 (s, 3H), 1.86-1.75 (m, 4H), 1.47-1.29 (m, 20H), 0.89 (t, 6H).

¹³C (CDCl₃, 50.3 MHz)—151.70, 151.13, 148.68, 148.45, 144.11, 134.79, 134.44, 132.98, 130.56, 129.43, 128.09, 127.72, 124.55, 123.44, 121.63, 111.97, 111.44, 69.20, 69.01, 31.95, 31.90, 29.53, 29.43, 29.35, 29.19, 29.21, 26.09, n22.82, 22.79, 21.79, 14.26.

FT-IR (KBr): 3903, 3838, 3736, 1726, 1647, 1599, 1569.

Anal. Cal.: C₃₆H₄₉N₃O₆S, C, 66.33; H, 7.58; N, 6.45. Found: C, 66.03; H, 7.48; N, 6.43

EI-MS: m/z 651

### (3) Synthesis of 1-(3-Nitrophenyl)-1-(3,4-dioctyloxyphenyl)-C61

In a 100-ml eggplant flask was placed 1.79 g (2.83 mmol) of 1-(3-nitrophenyl)-1-(3,4-dioctyloxyphenyl)methanone p-tolylsulfonylhydrazone. After purging the flask with nitrogen, 5.0 ml of pyridine was added, the mixture was stirred at room temperature for 10 minutes, combined with 153.0 mg (2.83 mmol) of sodium methoxide, and stirred at room temperature for 20 minutes. A solution of 1.22 g (1.70 mmol) of C₆₀ in 15 ml of ODCB was slowly added, followed by stirring at 80° C. for 24 hours. The reaction mixture was directly purified by silica gel column chromatography (initially hexane, then hexane/AcOEt=75/25). The resulting solid was dissolved in toluene, subjected to isomerization by refluxing for 24 hours, and thereby yielded 640 mg of the target compound in a yield of 32%.

¹H NMR (CDCl₃, 200 MHz): 8.93 (s, 1H), 8.46 (d, 1H), 8.26 (d, 1H) 7.70-7.53 (m, 2H), 6.98 (d, 1H), 6.81 (s, 1H), 4.13-3.98 (m, 4H), 1.83-1.79 (m, 4H), 1.43-1.28 (m, 20H), 0.87 (br s, 6H).

¹³C (CDCl₃, 50.3 MHz)—149.43, 148.50, 147.95, 147.17, 146.90, 144.92, 144.69, 144.49, 144.39, 144.13, 144.05, 143.54, 143.48, 142.72, 142.59, 141.91, 141.82, 141.18, 140.71, 138.20, 137.62, 136.51, 129.56, 125.35, 123.94, 122.97, 116.97, 113.21, 78.45, 69.88, 69.33, 69.04, 56.42, 31.96, 29.85, 29.64, 29.43, 26.21, 22.85, 14.31.

FT-IR (KBr): 2923, 2854, 1588, 1528, 1510, 1463, 1420, 1345, 1264.

Anal. Cal.: C₈₉H₄₁NO₄, C, 89.96; H, 3.48; N, 1.18. Found: C, 89.13; H, 3.43; N, 1.16.

### Example 27

### Solar Battery Cell Including 1-(4-Nitrophenyl)-1-(3,4-dioctyloxyphenyl)-C61 and P3HT

A solar battery cell was prepared by dissolving 15 mg of P3HT and 15 mg of 1-(4-nitrophenyl)-1-(3,4-dioctyloxyphenyl)-C61 in 1.0 ml of o-dichlorobenzene to give a solution; applying the solution via spin coating at a number of revolutions of 2000 rpm to give a film; and heating the coated film at 100° C. for 30 minutes. The cell, however, did not operate.

### Example 28

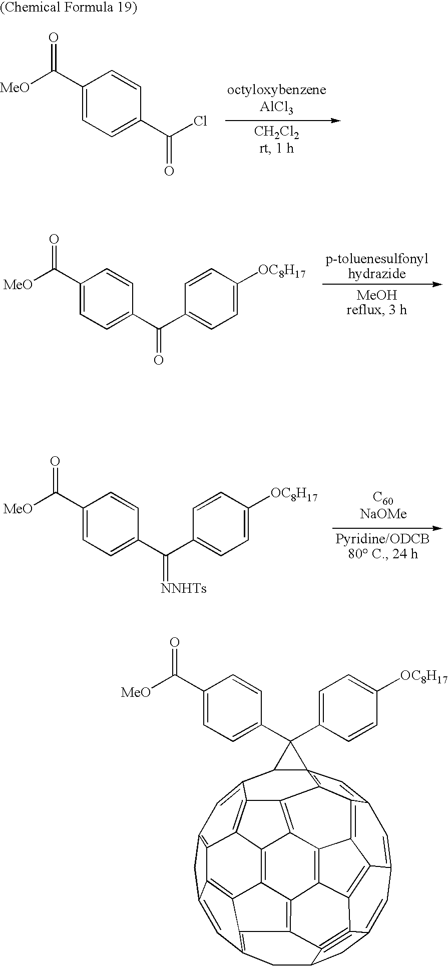

### (1) Synthesis of Methyl (4-Octyloxybenzoyl)-4-benzoate

In a 100-ml eggplant flask was placed 4.33 g (21.8 mmol) of 4-methoxycarbonylbenzoyl chloride. After purging the flask with nitrogen, 15 ml of CH₂Cl₂ was added, followed by ice-cooling. Next, 3.23 g (24.2 mmol) of aluminium trichloride was added, and a solution of 5.00 g (24.2 mmol) of octyloxybenzene in 5.0 ml of CH₂Cl₂ was slowly added. The mixture was stirred at room temperature for 2 hours and diluted with cold water. After extracting with methylene chloride, the organic phase was washed with water and dried over sodium sulfate. The solvent was distilled off on a rotary evaporator, the resulting crude product was recrystallized from hexane and thereby yielded 6.00 g of the target compound in a yield of 75%.

¹H NMR (CDCl₃, 200 MHz): 8.14 (d, J=8, 2H), 7.81-7.75 (m, 4H), 6.96 (d, J=8.4, 2H), 4.06 (t, 2H), 3.95 (s, 3H), 1.85-1.78 (m, 2H), 1.46-1.29 (m, 10H), 0.92 (t, 3H).

¹³C (CDCl₃, 50.3 MHz)-194.18, 165.96, 162.88, 141.92, 132.42, 132.32, 129.40, 129.02, 113.98, 68.32, 52.41, 31.90, 29.43, 29.32, 29.20, 26.11, 22.78, 14.26

FT-IR (KBr): 2955, 2923, 2874, 2857, 1721, 1604, 1572, 1507, 1433, 1415, 1404.

Anal. Cal.: C₂₃H₂₈O₄; C, 74.97; H, 7.66. Found: C, 74.44; H, 7.94

EI-MS: m/z 368

### (2) Synthesis of (4-Methoxycarbonylphenyl)-(4-octyloxyphenyl)methanone p-Tolylsulfonylhydrazone

In a 100 ml eggplant flask were placed 2.00 g (5.43 mmol) of methyl (4-octyloxybenzoyl)-4-benzoate and 3.03 g (16.3 mmol) of p-toluenesulfonylhydrazide, followed by refluxing for 12 hours. The reaction mixture was allowed to cool to room temperature, from which the solvent was distilled off on a rotary evaporator. The resulting crude product was purified by silica gel column chromatography (hexane/AcOEt=70/30) and thereby yielded 2.20 g of the target compound in a yield of 76%.

¹H NMR (CDCl₃, 200 MHz): 7.94-7.82 (m, 4H), 7.74 (s, 1H), 7.50 (d, J=8.4, 2H), 7.34 (d, 2H) 7.02 (m, 3H), 4.03 (t, 2H), 3.89 (s, 3H), 2.42 (s, 3H), 1.82-1.78 (m, 2H), 1.32-1.29 (m, 10H), 0.92 (t, 3H).

¹³C (CDCl₃, 50.3 MHz)—166.22, 160.19, 152.74, 143.96, 140.73, 135.20, 130.65, 129.63, 129.45, 129.14, 127.69, 127.34, 121.73, 115.55, 68.26, 52.25, 31.95, 29.46, 29.39, 29.28, 26.19, 22.83, 21.80, 14.30.

FT-IR (KBr): 3192, 2931, 2850, 1723, 1639.

Anal. Cal.: C₃₀H₃₆N₂O₅S, C, 67.14; H, 6.76; N, 5.52. Found: C, 67.10; H, 6.77; N, 5.32.

EI-MS: m/z 536

### (3) Synthesis of Methyl 1-(4-Octyloxyphenyl)-C61-4-benzoate

In a 100-ml eggplant flask was placed 1.30 g (2.42 mmol) of (4-methoxycarbonylphenyl)-(4-octyloxyphenyl)methanone p-tolylsulfonylhydrazone. After purging the flask with nitrogen, 5.0 ml of pyridine was added, the mixture was stirred at room temperature for 10 minutes, combined with 130.8 mg (2.42 mmol) of sodium methoxide, and stirred at room temperature for further 20 minutes. A solution of 1.04 g (1.45 mmol) of C₆₀ in 15 ml of ODCB was slowly added, followed by stirring at 80° C. for 24 hours. The reaction mixture was directly purified by silica gel column chromatography (toluene). The resulting solid was dissolved in toluene, subjected to isomerization by refluxing for 24 hours, and thereby yielded 317 mg of the target compound in a yield of 21%.

¹H NMR (CDCl₃, 200 MHz): 8.13 (m, 4H), 8.0 (d, J=8.6, 2H), 6.99 (d, J=8.6, 2H), 3.99 (t, 2H), 3.91 (s, 3H), 1.81-1.74 (m, 2H), 1.29-1.21 (m, 10H), 0.91 (t, 3H).

¹³C (CDCl₃, 50.3 MHz)—166.15, 158.65, 147.57, 144.95, 144.84, 144.76, 144.35, 144.29, 144.21, 144.0, 143.96, 143.47, 142.65, 142.61, 141.93, 141.85, 141.79, 140.56, 138.00, 137.65, 131.79, 130.52, 129.89, 129.68, 129.48, 114.62, 78.80, 68.06, 57.16, 52.27, 31.94, 29.52, 29.43, 29.39, 26.27, 22.83, 14.34

FT-IR (KBr): 2923, 2853, 1725, 1608, 1511, 1464, 1430, 1275, 1186, 1136, 1107

Anal. Cal.: C₈₃H₂₈O₃, C, 92.90; H, 2.63. Found: C, 92.17; H, 2.59

### Example 29

### Solar Battery Cell Including Methyl 1-(4-octyloxyphenyl)-C61-4-benzoate and P3HT

A solar battery cell was prepared by dissolving 15 mg of methyl 1-(4-octyloxyphenyl)-C61-4-benzoate in 1.0 ml of o-dichlorobenzene to give a solution; applying the solution via spin coating at a number of revolutions of 2000 rpm to give a film; and heating the coated film at 100° C. for 30 minutes. The properties of the cell were measured and found to be as follows:

E_{ff}=1.05%, FF=0.39, V_{oc}=0.60 V, I_{sc}=4.43 mA/cm²

### Example 30

### Synthesis of Methyl 1-(3,4-dimethoxyphenyl)-C61-4-benzoate

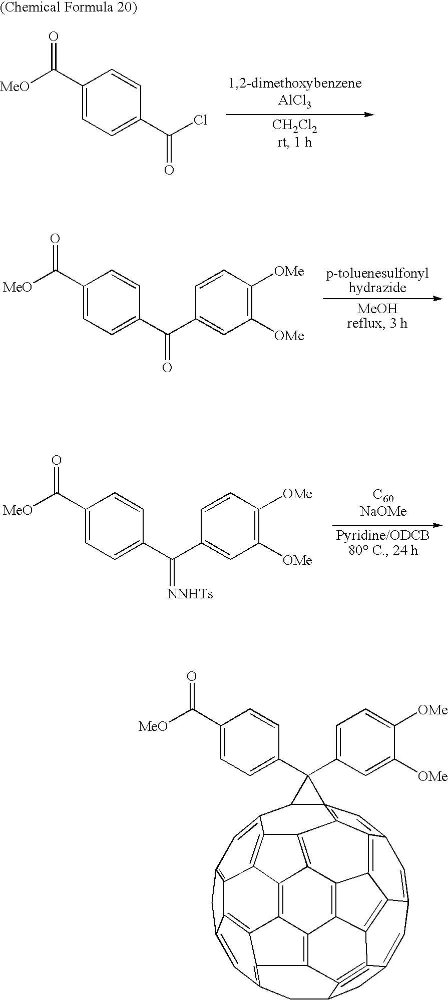

### (1) Synthesis of Methyl 4-(3,4-Dimethoxybenzoyl)benzoate

In a 100-ml eggplant flask was placed 1.86 g (10.1 mmol) of 4-methoxycarbonylbenzoyl chloride. After purging the flask with nitrogen, 10 ml of CH₂Cl₂ was added, followed by ice-cooling. Next, 1.35 g (10.1 mmol) of aluminium trichloride was added, and a solution of 1.40 g (9.12 mmol) of 1,2-dimethoxybenzene in 5 ml of CH₂Cl₂ was slowly added. The mixture was stirred at room temperature for 12 hours and diluted with cold water. After extracting with methylene chloride, the organic phase was washed with water and dried over sodium sulfate. The solvent was distilled off on a rotary evaporator, the resulting crude product was recrystallized from hexane, and thereby yielded 2.00 g of the target compound in a yield of 73%.

¹H NMR (CDCl₃, 200 MHz): 8.15 (d, J=8, 2H), 7.8 (d, J=8.2, 2H), 7.49 (d, 1H), 7.36 (dd, 1H), 6.90 (d, J=8.2, 1H), 3.96 (d, 9H).

¹³C (CDCl₃, 50.3 MHz)—194.20, 165.92, 153.08, 148.80, 141.82, 132.44, 129.33, 129.11, 125.42, 111.68, 109.63, 56.12, 56.03, 52.42.

FT-IR (KBr): 1725, 1647

Anal. Cal. C₁₇H₁₆O₅, C, 67.99; H, 5.37 Found: C, 66.35; H, 5.63.

EI-MS: m/z 300

### (2) Synthesis of (4-Methoxycarbonylphenyl)-(4-octyloxyphenyl)methanone p-Tolylsulfonylhydrazone

In a 100 ml eggplant flask were placed 1.70 g (5.66 mmol) of methyl 4-(3,4-dimethoxybenzoyl)benzoate and 3.16 g (17.0 mmol) of p-toluenesulfonylhydrazide, followed by refluxing for 5 hours. The reaction mixture was allowed to cool to room temperature, from which the solvent was distilled off on a rotary evaporator. The resulting crude product was purified by silica gel column chromatography (hexane/AcOEt=50/50) and thereby yielded 1.80 g of the target compound in a yield of 68%.

¹H NMR (CDCl₃, 200 MHz): 7.95-7.81 (m, 4H), 7.78 (d, 2H), 7.35-7.18 (m, 2H), 6.99 (d, 1H), 6.85 (d, 1H) 6.66 (d, 1H), 3.96-3.82 (m, 9H), 2.43 (s, 3H).

Anal. Cal. C₂₄H₂₄N₂O₆S, C, 61.52; H, 5.16; N, 5.98. Found: C, 61.32; H, 5.10; N, 5.97.

EI-MS: m/z 468

### (3) Synthesis of Methyl 1-(3,4-Dimethoxyphenyl)-C61-4-benzoate

In a 50-ml eggplant flask was placed 259 mg (0.550 mmol) of (4-methoxycarbonylphenyl)-(4-octyloxyphenyl)methanone p-tolylsulfonylhydrazone. After purging the flask with nitrogen, 3.0 ml of pyridine was added, the mixture was stirred at room temperature for 10 minutes, combined with 29.9 mg (0.550 mmol) of sodium methoxide, and stirred at room temperature for further 20 minutes. A solution of 239 mg (0.330 mmol) of C₆₀ in 10 ml of ODCB was slowly added, followed by stirring at 80° C. for 24 hours. The reaction mixture was directly purified by silica gel column chromatography (hexane/AcOEt=60:40). The resulting solid was dissolved in ODCB, subjected to isomerization by refluxing for 24 hours, and thereby yielded 112 mg of the target compound in a yield of 34%.

¹H NMR (CDCl₃, 200 MHz): 8.15 (m, 4H), 7.67 (dd, 1H), 7.53 (d, 1H), 6.99 (d, 1H), 3.97 (d, 9H).

¹³C (CDCl₃, 50.3 MHz)—166.19, 148.78, 148.63, 147.46, 144.95, 144.80, 144.42, 144.38, 144.34, 144.23, 144.00, 143.85, 143.50, 142.72, 142.63, 142.59, 141.94, 141.87, 141.80, 140.62, 140.58, 138.12, 137.70, 130.59, 130.30, 129.88, 129.60, 123.76, 113.84, 111.09, 78.72, 57.39, 56.46, 55.96, 52.32.

FT-IR (KBr): 1721, 1607, 1511, 1460, 1430, 1407, 1274, 1249.

Anal. Cal: C₇₇H₁₆O₄, C, 92.03; H, 1.60. Found: C, 91.13; H, 1.59

### Example 31

### Solar Battery Cell Including Methyl 1-(4-Octyloxyphenyl)-C61-4-benzoate and P3HT

A solar battery cell was prepared by dissolving 15 mg of methyl 1-(4-octyloxyphenyl)-C61-4-benzoate in 1.0 ml of o-dichlorobenzene to give a solution; applying the solution via spin coating at a number of revolutions of 2000 rpm to give a film; and heating the coated film at 100° C. for 30 minutes. The properties of the cell were measured and found to be as follows:

E_{ff}=0.022%, FF=0.18, V_{oc}=0.49 V, I_{sc}=0.25 mA/cm²

### Example 32

### Synthesis of Methyl 1-Phenyl-C61-4-benzoate

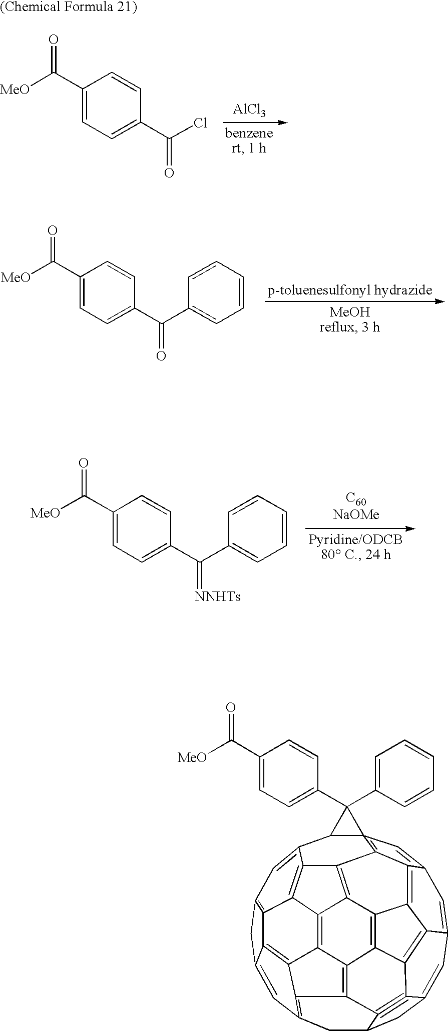

### (1) Synthesis of Methyl 4-Benzoylbenzoate

In a 100-ml eggplant flask was placed 5.00 g (25.2 mmol) of 4-methoxycarbonylbenzoyl chloride. After purging the flask with nitrogen, 20 ml of benzene was added, followed by ice-cooling. Next, 3.36 g (25.2 mmol) of aluminium trichloride was added, followed by refluxing for 24 hours. The reaction mixture was allowed to cool to room temperature, from which the solvent was distilled off on a rotary evaporator. The resulting crude product was purified by silica gel column chromatography (hexane/AcOEt=80/20) and thereby yielded 4.20 g of the target compound in a yield of 69%.

¹H NMR (CDCl₃, 200 MHz): 8.15-8.11 (m, 2H), 7.84-7.76 (m, 4H), 7.60-7.44 (m, 3H), 3.96 (s, 3H).

¹³C (CDCl₃, 50.3 MHz)—194.10, 165.75, 164.63, 164.53, 139.85, 135.45, 133.65, 132.20, 131.83, 131.71, 129.20, 128.64, 128.37, 128.31, 128.14, 128.05, 127.23, 51.41.

FT-IR (KBr): 1718, 1646

Anal. Cal. C₁₅H₁₂O₃, C, 74.99; H, 5.03 Found: C, 74.35; H, 4.97.

EI-MS: m/z 240

### (2) Synthesis of (4-Methoxycarbonylphenyl)-phenylmethanone p-Tolylsulfonylhydrazone

In a 100 ml eggplant flask were placed 1.00 g (4.16 mmol) of methyl 4-benzoylbenzoate and 2.30 g (12.5 mmol) of p-toluenesulfonylhydrazide. After purging the flask with nitrogen, 15 ml of MeOH was added, followed by refluxing for 12 hours. The reaction mixture was allowed to cool to room temperature, from which the solvent was distilled off on a rotary evaporator. The resulting crude product was purified by silica gel column chromatography (hexane/AcOEt=60/40) and thereby yielded 1.30 g of the target compound in a yield of 77%.

¹H NMR (CDCl₃, 200 MHz): 8.38 (d, J=5.6, 1H), 8.09 (d, J=8.2, 2H), 7.83-7.67 (m, 5H), 7.53 (d, 1H), 7.32-7.26 (m, 4H), 3.93 (s, 3H), 2.43 (s, 3H).

Anal. Cal. C₂₂H₂₀N₂O₄S, C, 64.69; H, 4.94; N, 6.86. Found: C, 64.54; H, 5.05; N, 6.97.

EI-MS: m/z 408

### (3) Synthesis of Methyl 1-(Phenyl-C61)-4-benzoate

In a 100-ml eggplant flask was placed 700 mg (1.71 mmol) of (4-methoxycarbonylphenyl)-phenylmethanone p-tolylsulfonylhydrazone. After purging the flask with nitrogen, 5.0 ml of pyridine was added, the mixture was stirred at room temperature for 10 minutes, combined with 92.6 mg (1.71 mmol) of sodium methoxide, and stirred at room temperature for further 20 minutes. A solution of 741 mg (1.03 mmol) of C₆₀ in 15 ml of ODCB was slowly added, followed by stirring at 80° C. for 24 hours. The reaction mixture was directly purified by silica gel column chromatography (hexane/AcOEt=80:20). The resulting solid was dissolved in toluene, subjected to isomerization by refluxing for 24 hours, and thereby yielded 335 mg of the target compound in a yield of 35%.

¹H NMR (CDCl₃, 200 MHz): 8.16-8.02 (m, 4H), 7.79 (m, 1H), 7.52-7.30 (m, 2H), 7.21-7.06 (m, 2H), 3.91 (s, 3H).

¹³C (CDCl₃, 50.3 MHz)—165.42, 165.18, 147.13, 147.08, 144.69, 144.62, 144.19, 144.14, 144.06, 143.84, 143.73, 143.30, 143.17, 142.46, 141.62, 141.23, 140.46, 140.27, 137.81, 137.36, 137.60, 136.01, 134.45, 133.40, 132.32, 130.55, 130.47, 120.71, 129.64, 129.51, 129.29, 129.10, 129.06, 128.83, 128.54, 128.05, 128.01, 127.20, 126.94, 124.57, 78.17, 57.36, 52.05, 51.89, 29.93, 21.74, 21.58.

FT-IR (KBr): 1725, 1608, 1432, 1273, 1178, 1102,

Anal. Cal. C₇₅H₁₂O₂, C, 95.33; H, 1.28 Found: C, 84.87; H, 1.23.

### Example 33

### Synthesis of Perfluorooctylethyl Phenyl C61-4-benzoate

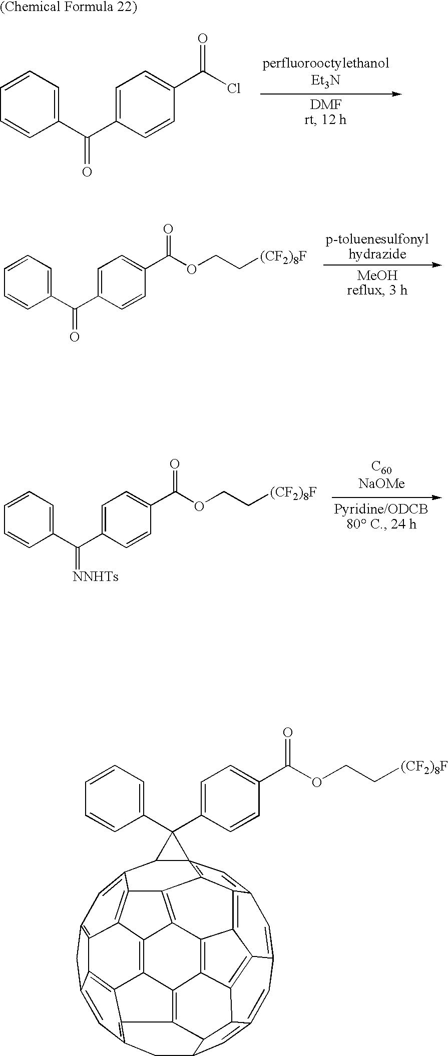

### (1) Synthesis of Perfluorooctylethyl 4-Benzoylbenzoate

In a 30-ml eggplant flask was placed 1.70 g (6.90 mmol) of 4-benzoylbenzoyl chloride. After purging the flask with nitrogen, 2.0 ml of DMF and 1.0 ml of Et₃N were added, followed by ice-cooling. A solution of 3.20 g (6.90 mmol) of 2-perfluorooctylethanol in 2.0 ml of DMF was slowly added, followed by stirring at room temperature for 12 hours. Precipitates were removed by filtration, and the solvent was distilled off on a rotary evaporator. The resulting crude product was purified by silica gel column chromatography (hexane/AcOEt=85/15) and thereby yielded 2.0 g of the target compound in a yield of 43%.

¹H NMR (CDCl₃, 200 MHz): 8.16-8.09 (m, 2H), 7.86-7.76 (m, 4H), 7.65-7.44 (m, 3H), 4.70 (m, 2H), 2.73-2.54 (m, 2H)

¹⁹F (CDCl₃, 188 MHz): −80.50 (t, 3F), −112.97 (s, 2F), −121.29 (br s, 6F), 122.11 (s, 2F), −122.88 (s, 2F), −125.50 (s, 2F).

¹³C (CDCl₃, 50.3 MHz)—195.40, 164.99, 141.47, 136.63, 132.77, 132.27, 129.88, 129.60, 129.38, 128.26, 57.29, 57.20, 31.22, 30.79, 30.36.

FT-IR (KBr): 1717, 1657, 1406, 1278, 1204, 1148, 1116.

Anal. Cal. C₂₄H₁₃F₁₇O₃, C, 42.87; H, 1.95. Found: C, 42.32; H, 1.79.

EI-MS: m/z 672

### (2) Synthesis of (4-Perfluorooctylethyloxycarbonylphenyl)phenylmethanone p-Tolylsulfonylhydrazone

In a 100 ml eggplant flask were placed 630 mg (0.937 mmol) of perfluorooctylethyl 4-benzoylbenzoate and 523.5 mg (2.81 mmol) of p-toluenesulfonylhydrazide, followed by refluxing for 12 hours. The reaction mixture was allowed to cool to room temperature, from which the solvent was distilled off on a rotary evaporator. The resulting crude product was purified by silica gel column chromatography (hexane/AcOEt=70/30) and thereby yielded 590 mg of the target compound in a yield of 75%.

¹H NMR (CDCl₃, 200 MHz): 8.18-8.13 (d, 1H), 7.99-7.82 (m, 3H), 7.70 (s, 1H), 7.55-7.08 (m, 8H), 4.70-4.57 (m, 2H), 2.67-2.46 (m, 2H), 2.43 (s, 3H).

¹⁹F (CDCl₃, 188 MHz): −80.53 (t, 3F), −112.98 (s, 2F), −121.29 (br s, 6F), −122.12 (s, 2F), −122.87 (s, 2F), −125.50 (s, 2F).

¹³C (CDCl₃, 50.3 MHz)—165.23, 164.71, 152.41, 144.11, 140.66, 135.96, 135.59, 135.14, 130.79, 130.20, 130.05, 129.91, 129.79, 129.33, 128.46, 128.14, 128.00, 127.72, 127.28, 126.44, 126.20, 125.99, 57.01, 31.19, 30.76, 30.32, 21.79.

FT-IR (KBr): 1722, 1406, 1276, 1240, 1204, 1169, 1149.

Anal. Cal. C₃₁H₂₁F₁₇N₂O₄S, C, 44.30; H, 2.52; N, 3.33. Found: C, 44.19; H, 2.12; N, 3.22.

EI-MS: m/z 840

### (3) Synthesis of Perfluorooctylethyl (Phenyl-C61)-4-benzoate

In a 50-ml eggplant flask was placed 500 mg (0.595 mmol) of (4-perfluorooctylethyloxycarbonylphenyl)phenylmethanone p-tolylsulfonylhydrazone. After purging the flask with nitrogen, 2.0 ml of ODCB was added, and the mixture was stirred under ice-cooling for 30 minutes. Next, 0.56 ml (0.892 mmol) of LiHMDS (1.6 M in THF) was added, the mixture was stirred under ice-cooling for 30 minutes, and a solution of 257 mg (0.356 mmol) of C₆₀ in 10 ml of ODCB was slowly added, followed by stirring at 80° C. for 24 hours. The solvent was distilled off on a rotary evaporator, and the resulting crude product was purified by silica gel column chromatography (toluene). The resulting solid was dissolved in toluene, subjected to isomerization by refluxing for 24 hours, and thereby yielded 253 mg of the target compound in a yield of 52%.

¹H NMR (CDCl₃, 200 MHz): 8.23-8.12 (m, 4H), 7.85-7.77 (m, 2H), 7.52-7.26 (m, 3H), 4.67 (m, 2H), 2.60 (m, 2H).

¹⁹F (CDCl₃, 188 MHz): −80.48 (t, 3F), −112.98 (s, 2F) −121.27 (br s, 6F), −122.09 (s, 2F), −122.88 (s, 2F), −125.48 (s, 2F).

¹³C (CDCl₃, 50.3 MHz)—165.26, 147.47, 147.39, 144.96, 144.88, 144.46, 144.16, 144.05, 143.57, 142.72, 141.96, 141.87, 140.72, 137.96, 137.78, 132.79, 132.26, 130.88, 130.79, 130.03, 129.89, 129.62, 129.40, 128.75, 128.28, 57.58, 57.06, 30.81, 29.88.

FT-IR (KBr): 1720, 1657, 1406, 1278, 1204, 1148, 1116.

Anal. Cal: C₈₄H₁₃F₁₇O₂, C, 73.27; H, 0.95. Found: C, 72.97; H, 0.93.

### Example 34

### Solar Battery Cell Including Perfluorooctylethyl Phenyl-C61-4-benzoate and P3HT

A solar battery cell was prepared by dissolving 15 mg of perfluorooctylethyl phenyl-C61-4-benzoate in 1.0 ml of o-dichlorobenzene to give a solution; applying the solution via spin coating at a number of revolutions of 2000 rpm to give a film; and heating the coated film at 100° C. for 30 minutes. The properties of the cell were measured and found to be as follows:

E_{ff}=0.36%, FF=0.38, V_{oc}=0.46 V, I_{sc}=2.03 mA/cm²

### Example 35

### Synthesis of 1,1′-bis(4-tert-butoxycarbonylphenyl)-C61

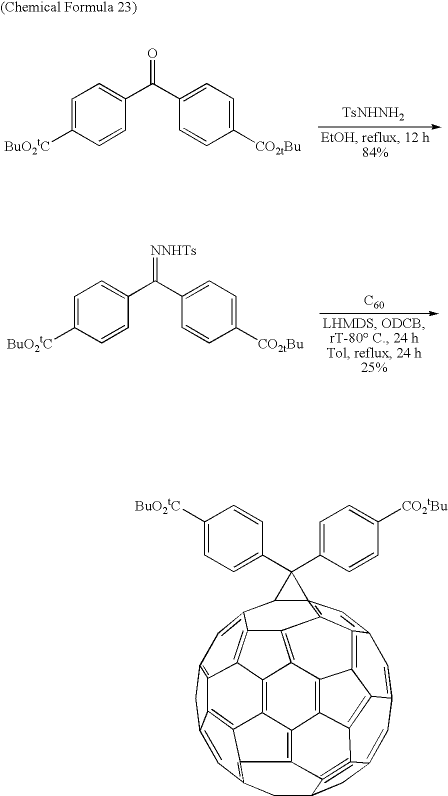

(1) Bis(4-tert-butoxycarbonylphenyl)methanone Tolylsulfonylhydrazone

In a 100-ml eggplant flask were placed 642 mg (1.68 mmol) of bis(4-tert-butoxycarbonylphenyl)methanone and 625 mg (3.36 mmol) of p-toluenesulfonylhydrazide. After purging the flask with nitrogen, 20 ml of EtOH was added, followed by refluxing for 12 hours. The reaction mixture was allowed to cool to room temperature, from which the solvent was distilled off on a rotary evaporator. The resulting crude product was purified by silica gel column chromatography (hexane to hexane/AcOEt=80/20) and thereby yielded 767 mg of the target compound in a yield of 84%.

¹H NMR (200 MHz, CDCl₃) δ 1.57 (9H, s), 1.63 (9H, s), 2.44 (3H, s), 7.50-7.16 (6H, m), 7.91-7.82 (4H, m), 8.15-8.11 (4H, m).

IR (KBr) ν/cm⁻¹ 2977.55, 2933.20, 1713.44, 1609.31, 1508.06, 1475.28, 1456.96, 1394.28, 1167.69, 1119.47, 1062.59, 1018.23, 979.66, 864.92, 847.56, 814.78, 779.10, 705.82, 682.68, 669.18, 623.86.

### (2) 1,1′-Bis(4-tert-butoxycarbonylphenyl)-C61

In a 50-ml eggplant flask was placed 504 mg (0.920 mmol) of bis(4-tert-butoxycarbonylphenyl)methanone tolylsulfonylhydrazone. After purging the flask with nitrogen, 2.0 ml of ODCB was added, and the mixture was stirred under ice-cooling for 30 minutes. Next, 0.86 ml (1.37 mmol) of LiHMDS (1.6 M in THF) was added, the mixture was stirred under ice-cooling for 30 minutes, and a solution of 527 mg (0.730 mmol) of C₆₀ in 8.0 ml of ODCB was slowly added, followed by stirring at 80° C. for 24 hours. The solvent was distilled off on a rotary evaporator, and the resulting crude product was purified by silica gel column chromatography (toluene to CH₂Cl₂). The resulting solid was dissolved in toluene, subjected to isomerization by refluxing for 24 hours, and thereby yielded 250 mg of the target compound in a yield of 25%.

¹³C NMR (600 MHz, CDCl₃) δ 28.10, 56.90, 81.03, 125.21, 128.14, 128.93, 130.00, 130.71, 131.94, 138.10, 140.10, 142.00, 142.40, 142.86, 142.92, 143.70, 144.30, 144.45, 144.56, 144.62, 145.05, 145.11, 147.24, 164.73.

IR (KBr) ν/cm⁻¹ 3422.06, 2973.70, 1715.37, 1608.34, 1474.31, 1456.96, 1405.85, 1366.32, 1291.11, 1164.79, 1117.55, 1018.23, 847.56, 763.67, 713.53.

UV/visible: (ODCB) [λₘₐₓ nm (log ε)] 431 (4.40), 331 (5.63)

### Example 36

### Solar Battery Cell Including 1,1′-Bis(4-tert-butoxycarbonylphenyl)-C61 and P3HT

A solar battery cell was prepared by dissolving 15 mg of 1,1′-bis(4-tert-butoxycarbonylphenyl)-C61 in 1.0 ml of o-dichlorobenzene to give a solution; applying the solution via spin coating at a number of revolutions of 2000 rpm to give a film; and heating the coated film at 100° C. for 30 minutes. The properties of the cell were measured and found to be as follows:

E_{ff}=0.75%, FF=0.49, V_{oc}=0.51 V, I_{sc}=2.97 mA/cm²

### Example 37

### Synthesis of 1,1′-Bis(4-hexyloxycarbonylphenyl)-C61

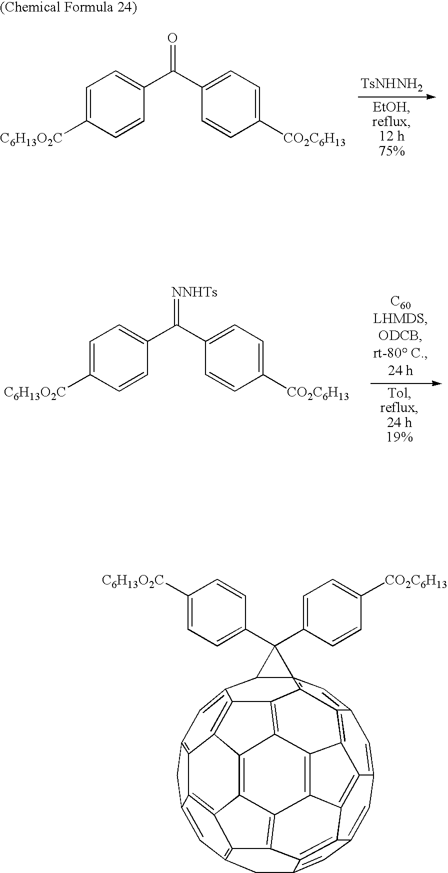

### (1) Bis(4-hexyloxycarbonylphenyl)methanone Tolylsulfonylhydrazone

In a 100-ml eggplant flask were placed 731 mg (1.66 mmol) of bis(4-hexyloxycarbonylphenyl)methanone and 620 mg (3.33 mmol) of p-toluenesulfonylhydrazide. After purging the flask with nitrogen, 20 ml of EtOH was added, followed by refluxing for 12 hours. The reaction mixture was allowed to cool to room temperature, from which the solvent was distilled off on a rotary evaporator. The resulting crude product was purified by silica gel column chromatography (hexane/AcOEt=80/20) and thereby yielded 759 mg of the target compound in a yield of 75%.

¹H NMR (200 MHz, CDCl₃) δ 0.95-0.86 (6H, m), 1.49-1.25 (12H, m), 1.68-1.85 (4H, m), 2.44 (3H, s), 4.40-4.26 (4H, m), 7.57-7.20 (6H, m), 7.96-7.83 (4H, m), 8.22-8.8.17 (2H, m).

IR (KBr) ν/cm⁻¹ 3184.86, 2956.34, 2930.31, 2858.95, 1935.22, 1719.23, 1595.81, 1466.60, 1406.82, 1350.89, 1273.75, 1170.58, 1105.01, 1064.51, 1018.23, 978.70, 878.42, 862.99, 813.81, 777.17, 756.92, 705.82, 666.29, 622.89.

### (2) 1,1′-Bis(4-hexyloxycarbonylphenyl)-C61

In a 50-ml eggplant flask was placed 606 mg (0.850 mmol) of bis(4-hexyloxycarbonylphenyl)methanone tolylsulfonylhydrazone. After purging the flask with nitrogen, 2.0 ml of ODCB was added, followed by stirring under ice-cooling for 30 minutes. Next, 0.80 ml (1.27 mmol) of LiHMDS (1.6 M in THF) was added, the mixture was stirred under ice-cooling for 30 minutes, and a solution of 488 mg (0.680 mmol) of C₆₀ in 8.0 ml of ODCB was slowly added, followed by stirring at 80° C. for 24 hours. The solvent was distilled off on a rotary evaporator, and the resulting crude product was purified by silica gel column chromatography (toluene to CH₂Cl₂). The resulting solid was dissolved in toluene, subjected to isomerization by refluxing for 24 hours, and thereby yielded 183 mg of the target compound in a yield of 19%.

¹H NMR (200 MHz, CDCl₃) δ 0.93-0.87 (6H, m), 1.49-1.22 (12H, m), 1.82-1.65 (4H, m), 2.44 (3H, s), 4.31 (4H, t, J=6.6), 8.21-8.8.12 (8H, m).

¹³C-NMR (200 MHz, CDCl₃) δ 14.70, 23.17, 26.33, 29.30, 32.04, 57.42, 65.83, 130.42, 130.80, 131.18, 138.26, 141.13, 142.25, 143.10, 143.93, 144.50, 144.65, 144.85, 145.27, 145.34, 147.43, 166.06.

IR (KBr) ν/cm⁻¹ 2951.52, 2925.48, 2855.10, 1720.19, 1608.34, 1508.06, 1464.67, 1406.82, 1271.19, 1176.36, 1105.98, 1019.19, 760.78, 714.50.

UV/visible: (ODCB) [λₘₐₓ nm (log ε)] 431.5 (4.45), 330.5 (5.68)

### Example 38

### Solar Battery Cell Including 1,1′-Bis(4-hexyloxycarbonylphenyl)-C61 and P3HT

A solar battery cell was prepared by dissolving 15 mg of 1,1′-Bis(4-hexyloxycarbonylphenyl)-C61 in 1.0 ml of o-dichlorobenzene to give a solution; applying the solution via spin coating at a number of revolutions of 2000 rpm to give a film; and heating the coated film at 100° C. for 30 minutes. The properties of the cell were measured and found to be as follows:

E_{ff}=1.31%, FF=0.58, V_{oc}=0.57 V, I_{sc}=3.91 mA/cm²

### Example 39

### 1-(4-Methylsulfonylphenyl)-1-(3,4-dioctyloxyphenyl)-C61

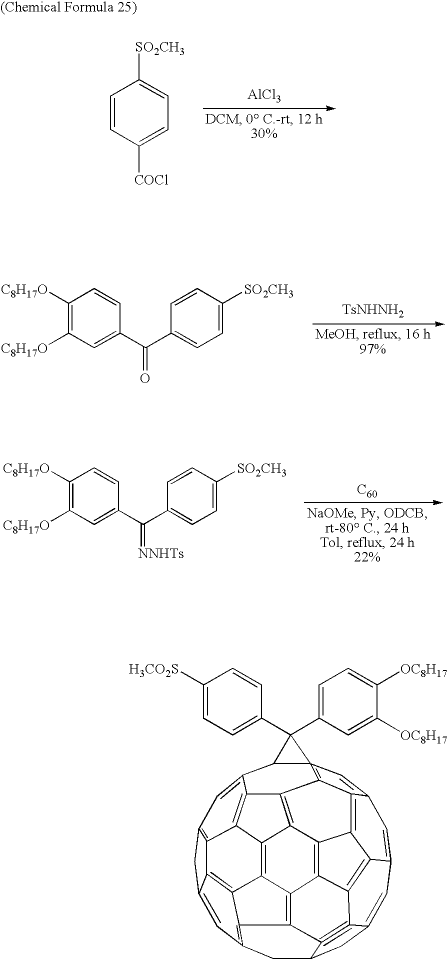

### (1) 1-(4-Methylsulfonylphenyl)-1-(3,4-dioctyloxyphenyl)methanone

In a 100-ml eggplant flask was placed 3.01 g (9.00 mmol) of 4-methylsulfonylbenzoyl chloride. After purging the flask with nitrogen, 10 ml of CH₂Cl₂ was added, followed by ice-cooling. Next, 1.19 g (9.00 mmol) of aluminium trichloride was added, and a solution of 1.64 g (7.50 mmol) of 1,2-dioctyloxybenzene in 5 ml of CH₂Cl₂ was slowly added. The mixture was stirred at room temperature for 12 hours and diluted with cold water. After extracting with methylene chloride, the organic phase was washed with water and dried over sodium sulfate. The solvent was distilled off on a rotary evaporator, and the resulting crude product was purified by silica gel column chromatography (hexane/ethyl acetate=70/30) and thereby yielded 1.41 g of the target compound in a yield of 30%.

¹H NMR (200 MHz, CDCl₃) δ 0.92-0.85 (6H, m), 1.52-1.29 (20H, m), 1.91-1.79 (4H, m), 3.10 (3H, s), 4.11-4.01 (4H, t, J=6.6), 6.86 (1H, d, J=8.4), 7.29-7.25 (1H, m), 7.47-7.46 (1H, m), 7.88-7.86 (2H, m), 8.07-8.02 (2H, m).

IR (KBr) ν/cm⁻¹ 3056.62, 3022.87, 2926.45, 2856.06, 1749.12, 1653.66, 1591.95, 1514.81, 1468.53, 1429.96, 1495.25, 1311.36, 1279.54, 1225.54, 1179.26, 1149.37, 1127.19, 1086.69, 1015.34, 966.16, 909.27, 875.56, 842.74, 780.06, 754.99, 842.74, 780.06, 754.99, 724.14, 697.14, 667.25.

### (2) 1-(4-Methylsulfonylphenyl)-1-(3,4-dioctyloxyphenyl)methanone Tolylsulfonylhydrazone

In a 100 ml eggplant flask were placed 1.40 g (2.70 mmol) of 1-(4-methylsulfonylphenyl)-1-(3,4-dioctyloxyphenyl)methanone and 1.51 g (8.10 mmol) of p-toluenesulfonylhydrazide. After purging the flask with nitrogen, 10 ml of MeOH was added, followed by refluxing for 12 hours. The reaction mixture was allowed to cool to room temperature, from which the solvent was distilled off on a rotary evaporator. The resulting crude product was purified by silica gel column chromatography (hexane/AcOEt=60/40) and thereby yielded 1.30 g of the target compound in a yield of 77%.

¹H NMR (200 MHz, CDCl₃) δ 0.91-0.85 (6H, m), 1.61-1.20 (20H, m), 1.98-1.75 (4H, m), 2.44 (3H, s), 3.03 (3H, s), 4.13-3.85 (4H, m), 6.66-6.53 (2H, m), 6.99-6.94 (1H, m), 7.35-7.31 (2H, m), 7.65-7.60 (2H, m), 7.86-7.82 (5H, m).

IR (KBr) ν/cm⁻¹ 3208.97, 3019.01, 2922.59, 2855.10, 1921.72, 1749.12, 1597.73, 1584.24, 1516.74, 1417.42, 1372.10, 1261.22, 1230.36, 1185.04, 1091.51, 1019.19, 985.45, 862.99, 852.38, 777.17, 721.25, 697.14, 651.82, 621.93.

### (3) 1-(4-Methylsulfonylphenyl)-1-(3,4-dioctyloxyphenyl)-C61

In a 100-ml eggplant flask were placed 1.80 g (2.62 mmol) of 1-(4-methylsulfonylphenyl)-1-(3,4-dioctyloxyphenyl)methanone tolylsulfonylhydrazone. After purging the flask with nitrogen, 4.0 ml of pyridine was added, the mixture was stirred at room temperature for 10 minutes, combined with 212 mg (3.93 mmol) of sodium methoxide, and stirred at room temperature for further 20 minutes. A solution of 1.13 g (2.62 mmol) of C₆₀ in 20 ml of ODCB was slowly added, followed by stirring at 80° C. for 24 hours. The reaction mixture was directly purified by silica gel column chromatography (hexane/AcOEt=98:2). The resulting solid was dissolved in toluene, subjected to isomerization by refluxing for 24 hours, and thereby yielded 422 mg of the target compound in a yield of 22%.

¹H NMR (200 MHz, CDCl₃) δ 0.91-0.84 (6H, m), 1.53-1.29 (20H, m), 1.90-1.75 (4H, m), 3.15 (3H, s), 4.12-3.98 (4H, m), 6.96 (1H, d, J=8.4), 7.62-7.57 (2H, m), 8.04 (2H, d, J=8), 8.30 (2H, d, J=8).

¹³C NMR (200 MHz, CDCl₃) δ 14.32, 14.36, 22.86, 26.22, 26.26, 29.45, 29.53, 29.63, 31.94, 31.96, 44.59, 56.78, 56.78, 69.03, 69.91, 78.41, 113.13, 117.13, 124.00, 127.72, 129.55, 131.45, 137.72, 138.19, 139.72, 140.66, 141.83, 141.91, 142.61, 142.68, 143.52, 144.04, 144.09, 144.18, 144.31, 144.40, 144.47, 144.71, 144.87, 144.91, 145.11, 146.98, 147.23, 148.46, 149.42.

### Example 40

### Solar Battery Cell Including 1-(4-Methylsulfonylphenyl)-1-(3,4-dioctyloxyphenyl)-C61 and P3HT

A solar battery cell was prepared by dissolving 15 mg of 1-(4-methylsulfonylphenyl)-1-(3,4-dioctyloxyphenyl)-C61 in 1.0 ml of o-dichlorobenzene to give a solution; applying the solution via spin coating at a number of revolutions of 2000 rpm to give a film; and heating the coated film at 100° C. for 30 minutes. The properties of the cell were measured and found to be as follows:

E_{ff}=1.24%, FF=0.50, V_{oc}=0.56 V, I_{sc}=4.43 mA/cm²

### Example 41

### 1-(3,4-Dioctyloxyphenyl)-1-(4-trifluoromethylsulfonylphenyl)-C61

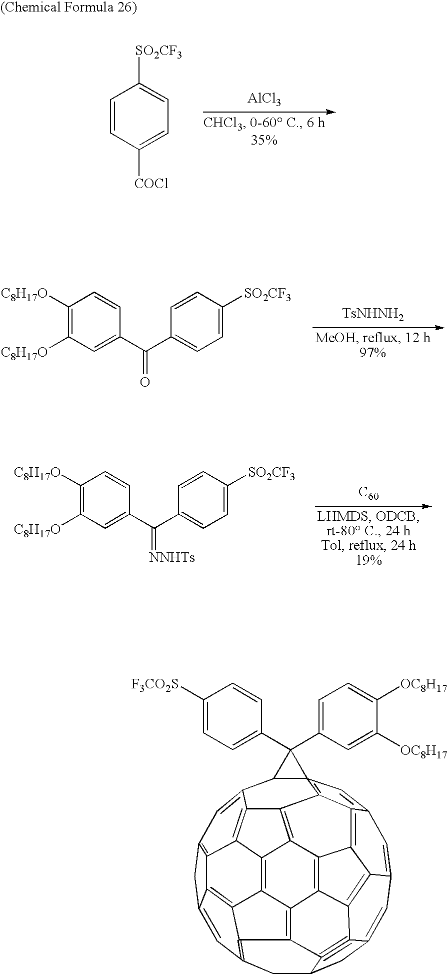

### (1) 1-(3,4-Dioctyloxyphenyl)-1-(4-trifluoromethylsulfonylphenyl)methanone

In a 100-ml eggplant flask was placed 4.22 g (15.5 mmol) of 4-trifluoromethylsulfonylbenzoyl chloride. After purging the flask with nitrogen, 10 ml of CHCl₃ was added, followed by ice-cooling. Next, 3.06 g (23.2 mmol) of aluminium trichloride was added, and a solution of 7.76 g (23.2 mmol) of 1,2-dioctyloxybenzene in 10 ml of CHCl₃ was slowly added. The mixture was stirred at 60° C. for 6 hours and diluted with cold water. After extracting with methylene chloride, the organic phase was washed with water and dried over sodium sulfate. The solvent was distilled off on a rotary evaporator, and the resulting crude product was purified by silica gel column chromatography (hexane/ethyl acetate=70/30) and thereby yielded 3.04 g of the target compound in a yield of 35%.

¹H NMR (200 MHz, CDCl₃) δ 0.88-0.79 (6H, m), 1.56-1.16 (20H, m), 1.98-1.79 (4H, m), 4.11-3.95 (4H, m), 6.86 (1H, d, J=8.4), 7.26-7.25 (1H, m), 7.48-7.47 (1H, m), 7.94 (2H, d, J=8.2), 8.14 (2H, d, J=8.0).

¹⁹F NMR (1 MHz, CDCl₃) δ 77.78, 77.85

IR (KBr) ν/cm⁻¹ 3093.26, 3030.59, 2957.30, 1964.14, 1751.84, 1580.38, 1469.49, 1430.92, 1399.10, 1348.00, 1302.68, 1279.54, 1139.72, 1073.19, 992.20, 955.56, 937.23, 894.49, 823.46, 770.42, 744.39, 732.82, 706.78, 684.61, 666.29, 621.93, 606.50.

### (2) 1-(3,4-Dioctyloxy)phenyl)-1-(4-trifluoromethylsulfonylphenyl)methanone Tolylsulfonylhydrazone

In a 100 ml eggplant flask were placed 2.93 g (5.14 mmol) of 1-(3,4-dioctyloxyphenyl)-1-(4-trifluoromethylsulfonylphenyl)methanone and 2.87 g (15.42 mmol) of p-toluenesulfonylhydrazide. After purging the flask with nitrogen, 30 ml of MeOH was added, followed by refluxing for 12 hours. The reaction mixture was allowed to cool to room temperature, from which the solvent was distilled off on a rotary evaporator. The resulting crude product was purified by silica gel column chromatography (hexane/AcOEt=90/10) and thereby yielded 1.30 g of the target compound in a yield of 77%.

¹H NMR (200 MHz, CDCl₃) δ 0.91-0.88 (6H, m), 1.77-1.15 (20H, m), 1.98-1.72 (4H, m), 2.45 (3H, s), 4.09-3.87 (4H, m), 6.67-6.44 (2H, m), 7.01-6.96 (1H, m), 7.50-7.17 (2H, m), 8.15-7.70 (6H, m).

¹⁹F NMR (1 MHz, CDCl₃) δ 77.62, 77.72.

IR (KBr) ν/cm⁻¹ 3567.66, 3210.9, 2928.38, 2857.02, 1597.73, 1579.41, 1514.81, 1469.49, 1419.35, 1371.14, 1348.96, 1257.36, 1219.76, 1197.58, 1168.65, 1139.72, 1073.19, 1019.19, 999.91, 857.2, 811.88, 769.46, 739.57, 727.03, 706.78, 695.21, 663.39, 634.47, 609.40.

### (3) 1-(3,4-Dioctyloxyphenyl)-1-(4-trifluoromethylsulfonylphenyl)-C61

In a 100-ml eggplant flask was placed 1.46 g (1.97 mmol) of 1-(3,4-dioctyloxyphenyl)-1-(4-trifluoromethylsulfonylphenyl)methanone. After purging the flask with nitrogen, 2.0 ml of ODCB was added, followed by stirring under ice-cooling for 30 minutes. Next, 1.84 ml (1.18 mmol) of LiHMDS (1.6M in THF) was added, the mixture was stirred under ice-cooling for 30 minutes, and a solution of 851 mg (1.18 mmol) of C₆₀ in 14 ml of ODCB was slowly added, followed by stirring at 80° C. for 24 hours. The solvent was distilled off on a rotary evaporator, and the resulting crude product was purified by silica gel column chromatography (hexane/AcOEt=98/2). The resulting solid was dissolved in toluene, subjected to isomerization by refluxing for 24 hours, and thereby yielded 292 mg of the target compound in a yield of 19%.

¹³C NMR (200 MHz, CDCl₃) δ 14.12, 22.64, 22.66, 26.02, 26.08, 26.88, 29.24, 29.27, 29.32, 29.35, 29.46, 31.55, 31.78, 31.81, 56.41, 68.95, 69.87, 76.79, 77.00, 77.21, 78.11, 113.23, 117.25, 118.67, 120.82, 124.33, 129.09, 130.67, 131.23, 132.14, 137.82, 138.50, 140.94, 140.99, 142.06, 142.09, 142.14, 142.86, 142.94, 142.98, 143.00, 143.03, 143.75, 143.79, 144.34, 144.40, 144.56, 144.68, 144.76, 144.87, 145.10, 145.17, 145.20, 145.23, 146.92, 147.18, 148.49, 148.78, 149.91.

IR (KBr) ν/cm⁻¹ 3446.17, 2923.56, 2853.17, 1592.91, 1509.03, 1464.67, 1425.14, 1372.10, 1265.07, 1250.61, 1216.86, 1199.51, 1138.76, 1074.16, 1018.23, 798.39, 742.46, 707.75, 634.47, 608.43.

UV/visible: (ODCB) [λₘₐₓ nm (log ε)] 429.5 (4.45), 329.5 (5.68).

### Example 42

Solar Battery Cell Including 1-(3,4-Dioctyloxyphenyl)-1-(4-trifluoromethylsulfonylphenyl)-C61 and P3HT

A solar battery cell was prepared by dissolving 15 mg of 1-(3,4-dioctyloxyphenyl)-1-(4-trifluoromethylsulfonylphenyl)-C61 in 1.0 ml of o-dichlorobenzene to give a solution; applying the solution via spin coating at a number of revolutions of 2000 rpm to give a film; and heating the coated film at 100° C. for 30 minutes. The properties of the cell were measured and found to be as follows:

E_{ff}=0.86%, FF=0.43, V_{oc}=0.48 V, I_{sc}=4.20 mA/cm²

While the above description is of the preferred embodiments of the present invention, it should be appreciated that the invention may be modified, altered, or varied without deviating from the scope and fair meaning of the following claims.

What is claimed is:

1. A methanofullerene derivative for use as an acceptor component for organic thin-film solar batteries, which is represented by Chemical Formula (1): 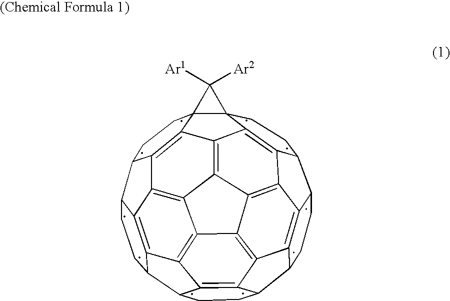
wherein Ar¹ and Ar² are the same or different substituents,
Ar¹ represents any one of: 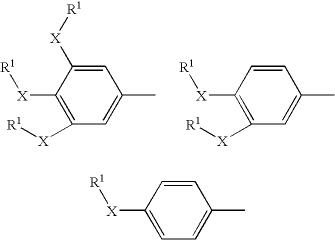
wherein R¹s each represent an alkyl group having one to fifteen carbon atoms, and X represents an oxygen or sulfur atom; and
Ar² represents YnC₆H₄, wherein Y represents a hydrogen or one or more substituents selected from the group consisting typically of CO₂R², R³SO₂, NO₂ group, and cyano group, wherein R² represents an alkyl group having one to fifteen carbon atoms, R³ represents a methyl group, a trifluoromethyl group, or a phenyl group; and “n” denotes an integer of from 1 to 5.

2. A methanofullerene-C₆₁ derivative for use as an acceptor component for organic thin-film solar batteries, which is represented by Chemical Formula (2): 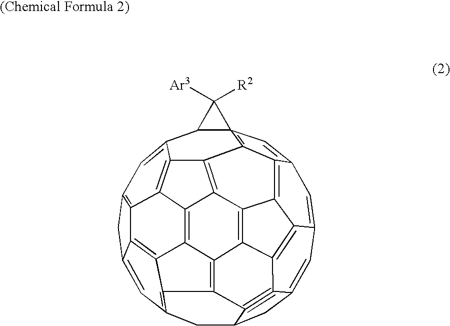
wherein Ar³ represents a phenyl group, a substituted phenyl group, or a benzothiazolyl group, wherein the substituted phenyl group is selected typically from a pentafluorophenyl group or 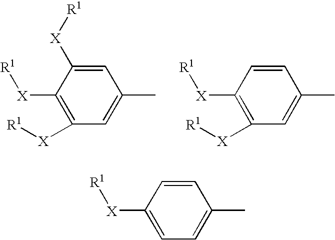
wherein R¹s each represent an alkyl group having one to fifteen carbon atoms, and X represents an oxygen or sulfur atom; and
R² represents a linear or branched alkyl group having one to twenty carbon atoms, -Q-X—Ar⁴, -Q-CO₂—CH₂Ar¹, or —CO₂—CH₂CH₂—Rf, wherein Q represents a (poly)methylene group having one to eight carbon atoms, X represents an oxygen atom or sulfur atom, and Ar⁴ represents a phenyl group, a substituted phenyl group, a naphthyl group, or a benzothiophene; wherein Ar¹ is as defined in Chemical Formula (1); and wherein Rf represents a perfluoroalkyl group having one to ten carbon atoms.

3. A methanofullerene-C₇₁ derivative corresponding to the fullerene derivative of claim 1, except for having a C₇₀ fullerene skeleton instead of the C₆₀ fullerene skeleton in Chemical Formula (1) and being represented by Chemical Formula (3): 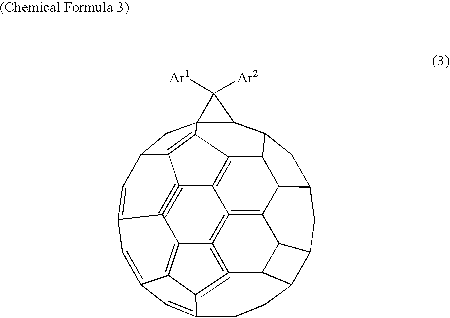
wherein Ar¹ and Ar² are as defined above.

4. A methanofullerene-C₇₁ derivative corresponding to the fullerene derivative of claim 2, except for having a C₇₀ fullerene skeleton instead of the C₆₀ fullerene skeleton in Chemical Formula (2) and being represented by Chemical Formula (4): 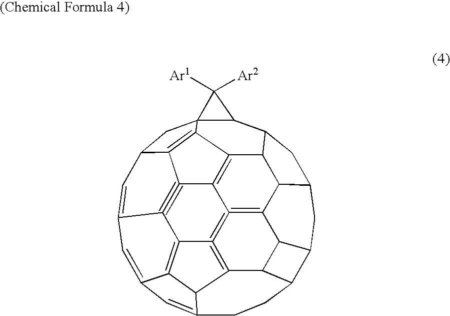
wherein Ar³ and R² are as defined above.

5. The methanofullerene derivative according to claim 1, wherein, in Chemical Formula (1), Ar¹ is a mono-substituted phenyl group, a di-substituted phenyl group, or a tri-substituted phenyl group, wherein R¹ is C₈H₁₇ and X is oxygen atom; and Ar² is YnC₆H₄ wherein Y is CO₂CH₃ and “n” is 1.

6. The methanofullerene-C₇₁ derivative according to claim 3, wherein, in Chemical Formula (3), Ar¹ is a mono-substituted phenyl group, a di-substituted phenyl group, or a tri-substituted phenyl group, wherein R¹ is C₈H₁₇ and X is oxygen atom; and Ar² is YnC₆H₄ wherein Y is CO₂CH₃ and “n” is 1.
